(19) United States
(12) Patent Application Publication
(10) Pub. No.: US 2025/0386560 A1
(43) Pub. Date: Dec. 18, 2025

(54) FIELD EFFECT TRANSISTOR INCLUDING A SEPARATION PATTERN AND METHOD OF MANUFACTURING THE SAME

(71) Applicant: SAMSUNG ELECTRONICS CO., LTD., SUWON-SI (KR)

(72) Inventors: YOUNGJIN YANG, Suwon-si (KR); KYUNAM PARK, Suwon-si (KR); WOOSEOK PARK, Suwon-si (KR); NAMHYUN LEE, Suwon-si (KR)

(21) Appl. No.: 19/025,691

(22) Filed: Jan. 16, 2025

(30) Foreign Application Priority Data
Jun. 12, 2024 (KR) 10-2024-0076576

(51) Int. Cl. H10D 62/10; H10D 30/00; H10D 30/01; H10D 30/43; H10D 62/17; H10D 64/27; H10D 84/01; H10D 84/83

(52) U.S. Cl. CPC H10D 62/115; H10D 30/43; H10D 30/502; H10D 62/121; H10D 62/235; H10D 64/514; H10D 64/518; H10D 84/832; H10D 30/014; H10D 30/0191; H10D 84/0128; H10D 84/0151

(57) ABSTRACT

A semiconductor device includes a substrate, an active pattern on the substrate, a first channel pattern and a second channel pattern on the active pattern, a separation pattern between the first channel pattern and the second channel pattern, a gate electrode on the first channel pattern and the second channel pattern, and a gate insulating layer between the first channel pattern and the gate electrode and between the second channel pattern and the gate electrode, wherein the separation pattern includes a body portion and a head portion on the body portion, and the head portion includes an insulating pattern and an insulating layer on the insulating pattern.

### CROSS-REFERENCE TO RELATED APPLICATIONS

This U.S. non-provisional patent application claims priority under 35 U.S.C. § 119 to Korean Patent Application No. 10-2024-0076576 filed on Jun. 12, 2024, in the Korean Intellectual Property Office, the entire contents of which are hereby incorporated by reference.

### BACKGROUND

### 1. Technical Field

The inventive concept relates to a field effect transistor and a method of manufacturing the same, and more particularly, relates to a field effect transistor including a separation pattern and a method of manufacturing the same.

### 2. Discussion of Related Art

A semiconductor device may include an integrated circuit including metal-oxide-semiconductor field effect transistors (MOSFET). As sizes and design rules of semiconductor devices have been reduced, a size of the MOSFETs may also be scaled down. Operating characteristics of semiconductor devices may be deteriorated as the MOSFETs are scaled down. For example, as a size of a MOSFET decreases, short-channel effects may increase. These short-channel effects may be caused by tunneling currents or leakage currents.

### SUMMARY

An object of the inventive concept is to provide a semiconductor device with improved electrical characteristics.

A semiconductor device according to some embodiments of the inventive concept may include a substrate, an active pattern on the substrate, a first channel pattern and a second channel pattern on the active pattern, a first separation pattern between the first channel pattern and the second channel pattern, a gate electrode on the first channel pattern and the second channel pattern, and a gate insulating layer between the first channel pattern and the gate electrode and between the second channel pattern and the gate electrode, wherein the first separation pattern includes a body portion and a head portion on the body portion, and the head portion includes an insulating pattern and an insulating layer on the insulating pattern.

A semiconductor device according to some embodiments of the inventive concept may include a substrate, an active pattern on the substrate, a first channel pattern and a second channel pattern disposed on the active pattern and each including a plurality of semiconductor patterns, a first separation pattern between the first channel pattern and the second channel pattern, and a gate electrode on the first channel pattern and the second channel pattern, wherein the first separation pattern includes a body portion and a head portion on the body portion, and a portion of an uppermost semiconductor pattern among the plurality of semiconductor patterns is in contact with the head portion of the first separation pattern.

A semiconductor device according to some embodiments of the inventive concept may include a substrate, a first active pattern and a second active pattern on the substrate, a first channel pattern and a second channel pattern on the first active pattern and the second active pattern, respectively, first source/drain patterns on opposing sides of the first channel pattern and second source/drain patterns on opposing sides of the second channel pattern, a first separation pattern between the first channel pattern and the second channel pattern of the first active pattern, a second separation pattern between the first channel pattern and the second channel pattern of the second active pattern, and a gate electrode covering the first channel pattern and the second channel pattern on the first active pattern and the second active pattern, wherein each of the first separation pattern and the second separation pattern includes a body portion and a head portion on the body portion, and the body portion and the head portion of at least one of the first separation pattern or the second separation pattern are spaced apart from each other.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a plan view for explaining a semiconductor device according to embodiments of the inventive concept.

FIG. 2A, FIG. 2B, FIG. 2C, and FIG. 2D are views for explaining semiconductor devices according to embodiments of the inventive concept, and are cross-sectional views taken along lines A-A′, B-B′, C-C′, and D-D′ in FIG. 1.

FIG. 3A and FIG. 3B are views for explaining a separation pattern of a semiconductor device according to embodiments of the inventive concept, and are enlarged views of region ‘P1’ of FIG. 2A.

FIG. 4 is a view for explaining a separation pattern of a semiconductor device according to embodiments of the inventive concept, and is an enlarged view of region ‘P2’ of FIG. 2B.

FIG. 5A and FIG. 5B are views for explaining the separation pattern of a semiconductor device according to embodiments of the inventive concept, and are enlarged views of region ‘P3’ of FIG. 2D.

FIG. 6A, FIG. 6B, FIG. 7, FIG. 8A, FIG. 8B, FIG. 8C, FIG. 9A, FIG. 9B, FIG. 9C, FIG. 10A, FIG. 10B, FIG. 10C, FIG. 11A, FIG. 11B, FIG. 12A, FIG. 12B, FIG. 12C, and FIG. 12D are views for explaining a method of manufacturing a semiconductor device according to embodiments of the inventive concept.

### DETAILED DESCRIPTION

Hereinafter, embodiments of the inventive concept will be described with reference to the attached drawings. The same reference numerals may refer to the same elements throughout the specification.

Aspects of the inventive concept may be embodied in different forms and should not be construed as limited to embodiments set forth herein. Rather, embodiments are provided so that this disclosure will be thorough and complete, and will fully convey the scope of the disclosure to those skilled in the art.

As used herein, each of phrases, such as “A or B”, “at least one of A and B”, “at least one of A or B”, “A, B, or C”, “at least one of A, B, and C”, and “at least one of A, B, or C” may include any one of the items listed together in the corresponding phrase or all possible combinations of the items.

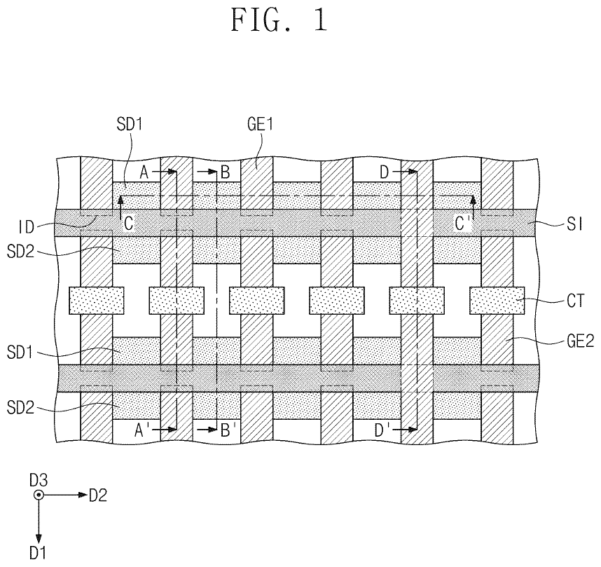

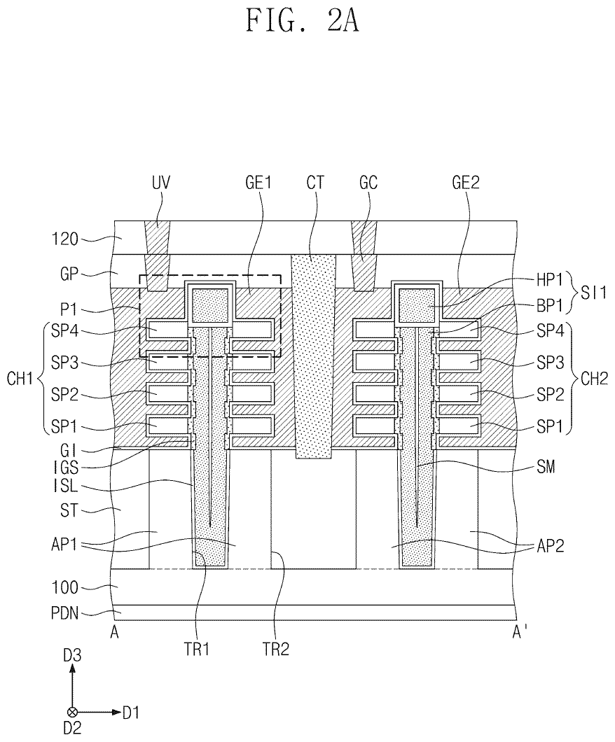

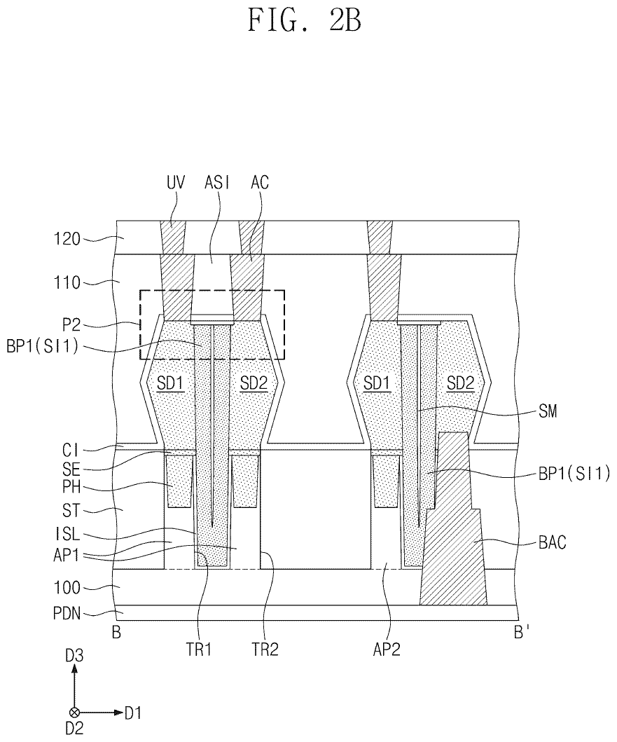

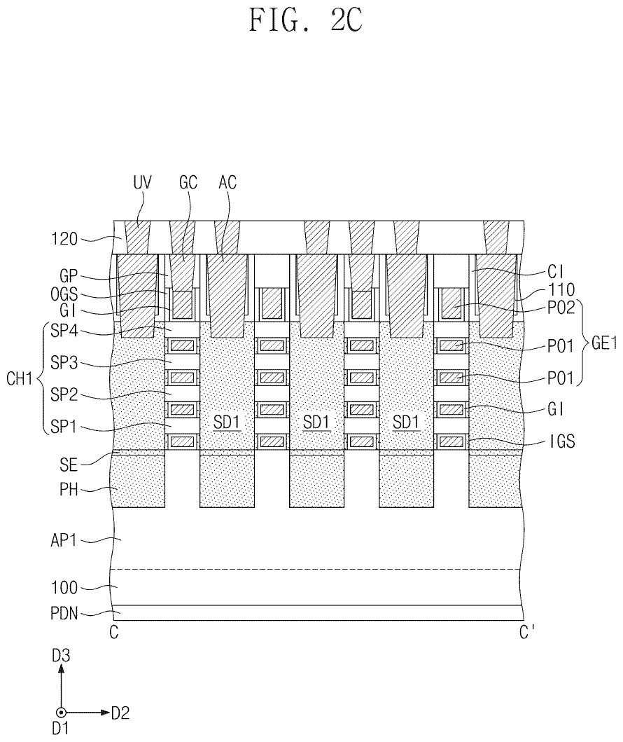

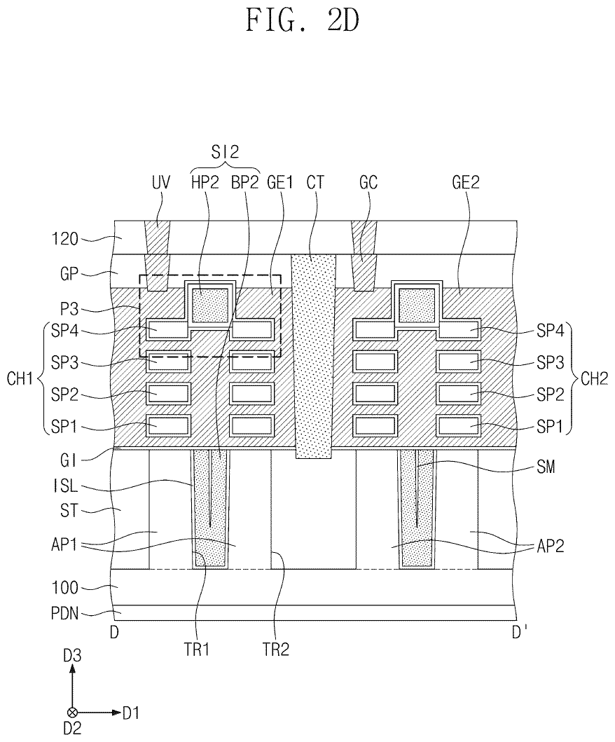

FIG. 1 is a plan view for explaining a semiconductor device according to embodiments of the inventive concept. FIG. 2A FIG. 2B, FIG. 2C, and FIG. 2D are views for explaining semiconductor devices according to embodiments of the inventive concept, and are cross-sectional views taken along lines A-A′, B-B′, C-C′, and D-D′ in FIG. 1.

In the drawings, a first direction D1 and a second direction D2 crossing the first direction D1 may form a plane parallel to an upper surface of the substrate 100. For example, the first direction D1 and the second direction D2 may be perpendicular to each other. A third direction D3 may be perpendicular to the first direction D1 and the second direction D2. For example, the third direction D3 may be perpendicular.

Referring to FIGS. 1, and 2A to 2D, a semiconductor device may include a substrate 100. A plurality of logic transistors constituting a logic circuit may be disposed on the substrate 100. The substrate 100 may be an insulating substrate including a silicon-based insulating layer. In detail, the substrate 100 may include at least one of silicon oxide, silicon nitride, or silicon oxynitride.

The substrate 100 may have a shape of a plate extending along a plane defined by the first direction D1 and the second direction D2.

First active patterns AP1 and second active patterns AP2 may be defined by a first trench TR1 and a second trench TR2 in the substrate 100. For example, the first active patterns AP1 and the second active patterns AP2 may be defined by the first trenches TR1 and the second trenches TR2. As shown in FIG. 2A, the first trenches TR1 may be disposed in the first active patterns AP1 or the second active patterns AP2, and the second trenches TR2 may be disposed between the first active patterns AP1 and the second active patterns AP2. The first active patterns AP1 and the second active patterns AP2 may be disposed in different portions of the substrate 100. For example, each of the first active patterns AP1 and the second active patterns AP2 may be a portion of the substrate 100 that protrudes in the third direction D3 perpendicular to the upper surface of the substrate 100. However, the substrate 100, and the first and second active patterns AP1 and AP2 may be defined to have different configurations.

Each of the first active patterns AP1 and the second active patterns AP2 may extend in the second direction D2. The first active patterns AP1 and the second active patterns AP2 may be spaced apart from each other in the first direction D1 by a device isolation pattern ST. The first active patterns AP1 or the second active patterns AP2 may be spaced apart from each other in the first direction D1 by first and second separation patterns SI and SI2.

The device isolation pattern ST may be provided on the substrate 100. The device isolation pattern ST may be disposed in the second trenches TR2. The device isolation pattern ST may fill the second trenches TR2. When viewed in a plan view, the device isolation pattern ST may surround the first and second active patterns AP1 and AP2. An upper surface of the device isolation pattern ST may be coplanar with upper surfaces of the first and second active patterns AP1 and AP2, but is not limited thereto. The device isolation pattern ST may include an insulating material. For example, the device isolation pattern ST may include an insulating material such as silicon oxide.

A first channel pattern CH1 and a second channel pattern CH2 may be provided on each of the first and second active patterns AP1 and AP2, respectively. The first channel pattern CH1 and the second channel pattern CH2 may be adjacent to each other in the first direction D1. The first channel pattern CH1 and the second channel pattern CH2 may be spaced apart from each other in the first direction D1 with the first or second separation patterns SI1 and SI2 interposed therebetween. Each of the first channel pattern CH1 and the second channel pattern CH2 may be provided in the plural and may be spaced apart from each other in the second direction D2.

Each of the first and second channel patterns CH1 and CH2 may include a plurality of semiconductor patterns. For example, each of the first and second channel patterns CH1 and CH2 may include a first semiconductor pattern SP1, a second semiconductor pattern SP2, a third semiconductor pattern SP3, and a fourth semiconductor pattern SP4. However, embodiments are not limited thereto, and two or more semiconductor patterns of the first and second channel patterns CH1 and CH2 may be provided. The first to fourth semiconductor patterns SP1, SP2, SP3, and SP4 may be spaced apart from each other in a vertical direction (e.g., the third direction D3). For example, the first to fourth semiconductor patterns SP1, SP2, SP3, and SP4 may include crystalline silicon. Each of the first to fourth semiconductor patterns SP1, SP2, SP3, and SP4 may be a nanosheet. However, the present inventive concept is not limited to the type or shape of the semiconductor patterns.

First source/drain patterns SD1 and second source/drain patterns SD2 may be provided on each of the first and second active patterns AP1 and AP2, respectively. For example, a first source/drain pattern SD1 and a second source/drain pattern SD2 may be provided on the first active pattern AP1, and a first source/drain pattern SD1 and a second source/drain pattern SD2 may be provided on the second active pattern AP2. The first source/drain patterns SD1 may be disposed on opposing sides of the first channel pattern CH1. The first source/drain patterns SD1 may be electrically connected to end portions of the first channel pattern CH1. The second source/drain patterns SD2 may be disposed on opposing sides of the second channel pattern CH2. The second source/drain patterns SD2 may be electrically connected to end portions of the second channel pattern CH2. Further, the first source/drain patterns SD1 may be disposed between a plurality of first channel patterns CH1, and the second source/drain patterns SD2 may be disposed between a plurality of second channel patterns CH2.

The first and second source/drain patterns SD1 and SD2 may include impurity regions. For example, the first and second source/drain patterns SD1 and SD2 may include impurity regions having a first conductivity type (e.g., p-type) or a second conductivity type (e.g., n-type). For example, the first and second source/drain patterns SD1 and SD2 may include impurity regions having the same conductivity type or may include impurity regions having different conductivity types.

Seed patterns SE may be provided on the first and second active patterns AP1 and AP2. The seed patterns SE may be provided between the first and second source/drain patterns SD1 and SD2 and the first and second active patterns AP1 and AP2. Each of the first and second source/drain patterns SD1 and SD2 may be an epitaxial pattern formed through a selective epitaxial growth process (SEG) using the seed patterns SE as a seed. For example, the first and second source/drain patterns SD1 and SD2 may include silicon or silicon-germanium.

A first gate electrode GE1 may be provided on the first active patterns AP1. A second gate electrode GE2 may be provided on the second active patterns AP2. The first gate electrode GE1 may be disposed on the first and second channel patterns CH1 and CH2 of the first active patterns AP1. The second gate electrode GE2 may be disposed on the first and second channel patterns CH1 and CH2 of the second active patterns AP2. For example, each of the first and second gate electrodes GE1 and GE2 may surround at least a portion of each of the first to fourth semiconductor patterns SP1, SP2, SP3, and SP4 of the first and second channel patterns CH1 and CH2. The first gate electrode GE1 and the second gate electrode GE2 may be spaced apart in the first direction D1. The first gate electrode GE1 and the second gate electrode GE2 may be spaced apart in the first direction D1 by cutting patterns CT.

Additionally, each of the first and second gate electrodes GE1 and GE2 may include inner electrodes PO1 and outer electrodes PO2. Each of the inner electrodes PO1 may be disposed between the first semiconductor pattern SP1 and the first or second active patterns AP1 and AP2, and between the first to fourth semiconductor patterns SP1, SP2, SP3, and SP4. The outer electrode PO2 may be disposed on the fourth semiconductor pattern SP4, which may be the uppermost semiconductor pattern among the first to fourth semiconductor patterns SP1, SP2, SP3, and SP4. The first and second gate electrodes GE1 and GE2 may include at least one of a metal material (e.g., Ti, Mo, W, Cu, Al, Ta, Ru, Ir, or Co), metal nitride (e.g., nitride of Ti, Mo, W, Cu, Al, Ta, Ru, Ir, or Co), or polysilicon doped with impurities. However, aspects are not limited thereto, and the first and second gate electrodes GE1 and GE2 may be formed of other materials. Separation patterns SI (see FIG. 1) may be provided on the substrate 100. When viewed in a plan view, each of the separation patterns SI may extend in the second direction D2. The separation patterns SI may be spaced apart from each other in the first direction D1. For example, the separation patterns SI may include an insulating material such as silicon oxide, silicon nitride, silicon oxynitride, or silicon oxycarbide (SiOC). Additionally, the separation patterns SI may be made of a single layer or a multilayer layer. For example, a multilayer layer of the separation pattern SI may contain the same material or different insulating materials.

The separation patterns SI may include first separation patterns SI1 and second separation patterns SI2. Each of the first and second separation patterns SI1 and SI2 may be disposed in first trenches TR1 and may have a shape extending in the third direction D3. Each of the first and second separation patterns SI1 and SI2 may be disposed between portions of the first active patterns AP1 or portions of the second active patterns AP2 that are adjacent to each other in the first direction D1. That is, each of the first and second separation patterns SI1 and SI2 may extend into the first active patterns AP1 or the second active patterns AP2 adjacent to each other in the first direction D1. Additionally, each of the first and second separation patterns SI1 and SI2 may be disposed between the first channel pattern CH1 and the second channel pattern CH2 that are adjacent to each other in the first direction D1.

Each of the first separation patterns SI1 may include a first body portion BP1 and a first head portion HP1 disposed on the first body portion BP1. The first body portion BP1 may have a shape extending in the third direction D3. A portion of the first body portion BP1 may be disposed in the first trench TR1. For example, the first body portion BP1 may extend between the first and second channel patterns CH1 and CH2 that may be adjacent to each other in the first direction D1 in the first trench TR1. The first body portion BP1 may be in contact with a side of the first to fourth semiconductor patterns SP1, SP2, SP3, and SP4 of the first channel pattern CH1 and a side of the first to fourth semiconductor patterns SP1, SP2, SP3, and SP4 of the second channel pattern CH2. As a result, the first and second gate electrodes GE1 and GE2 adjacent to the first separation patterns SI1 may surround three sides of each of the first to fourth semiconductor patterns SP1, SP2, SP3, and SP4.

The first head portion HP1 may be disposed on an upper end of the first body portion BP1, and the first body portion BP1 and the first head portion HP1 may be in contact with each other. The first body portion BP1 may have a seam SM disposed therein. The seam SM inside the first body portion BP1 may have a shape extending in the third direction D3 along the first body portion BP1. The seam SM inside the first body portion BP1 may be in contact with the first head portion HP1. For example, the seam SM inside the first body portion BP1 may be in contact with the first head portion HP1 at an upper surface of the first body portion BP1. That is, the seam SM inside the first body portion BP1 may be capped by the first head portion HP1.

Each of the second separation patterns SI2 may include a second body portion BP2 and a second head portion HP2 disposed on the second body portion BP2. The second body portion BP2 may be disposed in the first trench TR1. The second body portion BP2 may have a shape extending in the third direction D3 in the first trench TR1. The second body portion BP2 may extend from a lower surface of the first and second gate electrodes GEL and GE2. For example, the second body portion BP2 may include an upper surface disposed at the lower surface of the first and second gate electrodes GE1 and GE2 and the second body portion BP2 may not extend between the first and second channel patterns CH1 and CH2 adjacent to each other in the first direction D1. The second body portion BP2 may be spaced apart from the first to fourth semiconductor patterns SP1, SP2, SP3, and SP4 of the first and second channel patterns CH1 and CH2. For example, the second body portion BP2 may be spaced apart from the first to fourth semiconductor patterns SP1, SP2, SP3, and SP4 of the first and second channel patterns CH1 and CH2 in the third direction D3. As a result, the first and second gate electrodes GE1 and GE2 adjacent to the second separation patterns SI2 may completely or partially surround four sides of each of the first to fourth semiconductor patterns SP1, SP2, SP3, and SP4. The second head portion HP2 may be disposed on the second body portion BP2, and the second body portion BP2 and the second head portion HP2 may be spaced apart from each other in the third direction D3. The second body portion BP2 may have a seam SM disposed therein. The seam SM inside the second body portion BP2 may have a shape extending in the third direction D3 along the second body portion BP2. The seam SM inside the second body portion BP2 may be capped by a gate insulating layer GI.

Additionally, the first body portion BP1 of the first separation patterns SI1 may be disposed between the first and second source/drain patterns SD1 and SD2. Accordingly, the first and second source/drain patterns SD1 and SD2 adjacent to each other in the first direction D1 may be spaced apart from each other.

An insulating shell layer ISL may be provided. The insulating shell layer ISL may be provided between the first active patterns AP1 and the first and second separation patterns SI1 and SI2, and between the second active patterns AP2 and the first and second separation patterns SI1 and SI2. That is, the insulating shell layer ISL may be disposed between the first body portion BP1 and the first and second active patterns AP1 and AP2, and between the second body portion BP2 and the first and second active patterns AP1 and AP2. The insulating shell layer ISL may be disposed on inner walls of the first trenches TR1. For example, the insulating shell layer ISL may cover inner walls of the first trenches TR1 with a uniform thickness. For example, the insulating shell layer ISL may include an insulating material such as silicon oxide.

Inner gate spacers IGS may be disposed between the first source/drain patterns SD1, between the second source/drain patterns SD2, and on the opposing sides of the first body portion BP1 of the first separation patterns SI1. More specifically, the inner gate spacers IGS may be disposed between the first and second channel patterns CH1 and CH2 and the first body portion BP1 of the first separation patterns SI1 and between the inner electrode PO1 of the first and second gate electrode GE1 and GE2 and the first and second source/drain patterns SD1 and SD2.

A gate insulating layer GI may be provided. The gate insulating layer GI may be disposed between the first and second gate electrodes GE1 and GE2 and the first to fourth semiconductor patterns SP1, SP2, SP3, and SP4 of the first and second channel patterns CH1 and CH2. The gate insulating layer GI adjacent to the first separation patterns SI1 may be disposed on the top, bottom, and a side of each of the first to fourth semiconductor patterns SP1, SP2, SP3, and SP4. The gate insulating layer GI adjacent to the first separation patterns SI1 may expose a side of each of the first to fourth semiconductor patterns SP1, SP2, SP3, and SP4. The gate insulating layer GI adjacent to the second separation patterns SI2 may be disposed on the top, bottom, and opposing sides of each of the first to fourth semiconductor patterns SP1, SP2, SP3, and SP4. In addition, the gate insulating layer GI may cover opposing sides of the first body portion BP1 of the first separation patterns SI1 and the first head portion HP1 and the second head portion HP2 of the second separation patterns SI2. The gate insulating layer GI may extend between the first and second gate electrodes GE1 and GE2, the device isolation pattern ST, and the first and second active patterns AP1 and AP2. The gate insulating layer GI may also be disposed between the outer electrode PO2 and outer gate spacers OGS. For example, the gate insulating layer GI may include silicon oxide, silicon oxynitride, and/or a high dielectric constant material. In this specification, a high dielectric constant material may be a material having a higher dielectric constant than silicon oxide.

A pair of outer gate spacers OGS may be provided on opposing sides of the outer electrode PO2 of each of the first and second gate electrodes GEL and GE2. For example, the outer gate spacers OGS may include at least one of SiON, SiCN, SiOCN, or SiN. Additionally, the outer gate spacers OGS may be composed of a single layer or a multilayer layer having the same or different insulating materials.

Gate capping patterns GP may be provided on the first and second gate electrodes GE1 and GE2. The gate capping patterns GP may be disposed on an upper surface of the outer electrode PO2 of the first and second gate electrodes GE1 and GE2. For example, the gate capping patterns GP may cover the upper surface of the outer electrode PO2 of the first and second gate electrodes GE1 and GE2. The gate capping patterns GP may include at least one of SiON, SiCN, SiOCN, or SiN. However, aspects are not limited thereto, and the gate capping patterns GP may be formed of other materials.

A first upper insulating layer 110 may be provided on the substrate 100. The first upper insulating layer 110 may cover the first and second source/drain patterns SD1 and SD2. An upper surface of the first upper insulating layer 110 may be substantially coplanar with upper surfaces of the gate capping patterns GP. The first upper insulating layer 110 may include an insulating material such as silicon oxide. However, aspects are not limited thereto, and the first upper insulating layer 110 may be formed of other materials.

A capping insulating layer CI may be provided between the first upper insulating layer 110 and the first and second source/drain patterns SD1 and SD2. The capping insulating layer CI may cover surfaces of the first and second source/drain patterns SD1 and SD2. The capping insulating layer CI may extend onto the device isolation pattern ST. For example, the capping insulating layer CI may include an insulating material different from that of the first upper insulating layer 110. According to an embodiment, the capping insulating layer CI may be composed of a single layer or a multilayer layer including the same or different insulating materials.

Active contacts AC may be provided. The active contacts AC may be provided in the first upper insulating layer 110. The active contacts AC may penetrate a portion of the first upper insulating layer 110 in the third direction D3. Each of the active contacts AC may be connected to a corresponding source/drain pattern of the first and second source/drain patterns SD1 and SD2. For example, the active contacts AC may include at least one of a metal material (e.g., Ti, Mo, W, Cu, Al, Ta, Ru, Ir, or Co) or metal nitride (e.g., nitride of Ti, Mo, W, Cu, Al, Ta, Ru, Ir, or Co).

According to an embodiment, an additional separation pattern ASI including an insulating material may be provided between the active contacts AC. The additional separation pattern ASI may be omitted and the first upper insulating layer 110 may be provided between the active contacts AC.

According to an embodiment, a silicide pattern may be provided between the active contacts AC and the first and second source/drain patterns SD1 and SD2. For example, the silicide pattern may be a layer formed at the top of the first and second source/drain patterns SD1 and SD2.

Gate contacts GC may be provided in the gate capping patterns GP. The gate contacts GC may penetrate the gate capping patterns GP in the third direction D3. The gate contacts GC may be connected to the first and second gate electrodes GE1 and GE2. For example, the gate contacts GC may include at least one of a metal material (e.g., Ti, Mo, W, Cu, Al, Ta, Ru, Ir, or Co) or metal nitride (e.g., nitride of Ti, Mo, W, Cu, Al, Ta, Ru, Ir, or Co).

Each of the cutting patterns CT may be provided between the first and second gate electrodes GE1 and GE2. The cutting patterns CT may extend in the third direction D3 between adjacent first and second gate electrodes GE1 and GE2. The cutting patterns CT may penetrate an upper portion of the device isolation pattern ST. For example, each of the cutting patterns CT may have a vertical length greater than a vertical length of each of the first and second gate electrodes GE1 and GE2. Accordingly, the first and second gate electrodes GE1 and GE2 may be spaced apart from each other in the first direction D1.

A second upper insulating layer 120 may be provided. The second upper insulating layer 120 may be provided on the first upper insulating layer 110. The second upper insulating layer 120 may cover the first upper insulating layer 110, the gate capping patterns GP, the active contacts AC, and the gate contacts GC. The second upper insulating layer 120 may include substantially the same insulating material as the first upper insulating layer 110. However, aspects are not limited thereto, and the first upper insulating layer 110 and the second upper insulating layer 120 may be formed of different materials.

Upper vias UV may be provided. The upper vias UV may be provided in the second upper insulating layer 120. The upper vias UV may penetrate the second upper insulating layer 120. Each of the upper vias UV may be connected to corresponding active contacts AC and gate contacts GC. For example, the upper vias UV may include a metal material (e.g., Ti, Mo, W, Cu, Al, Ta, Ru, Ir, or Co).

According to an embodiment, a metal layer including wiring patterns and via patterns may be provided on the upper vias UV. The wiring patterns and via patterns of the metal layer may be electrically connected to the upper vias. Adjacent logic transistors may exchange electrical signals with each other through the metal layer. A plurality of metal layers may be provided and may be stacked on each other in the third direction D3.

A power transmission network layer PDN may be provided on a lower surface or a backside of the substrate 100. For example, the power transmission network layer PDN may include a wiring network for applying a source voltage. Alternatively, the power transmission network layer PDN may include a wiring network for applying a drain voltage. According to an embodiment, the power transmission network layer PDN may include wiring patterns and via patterns. The wiring patterns and via patterns may be stacked in the third direction D3 and may be electrically connected to each other.

A backside active contact BAC may be provided. The backside active contact BAC may be provided between the power transmission network layer PDN and the first and second source/drain patterns SD1 and SD2. The backside active contact BAC may be connected to at least one of the first or second source/drain patterns SD1 and SD2. The backside active contact BAC may be electrically connected to the wiring patterns and via patterns of the power transmission network layer PDN. Accordingly, at least one of the first or second source/drain patterns SD1 and SD2 may be electrically connected to the power transmission network layer PDN. For example, the backside active contact BAC may include at least one of a metal material (e.g., Ti, Mo, W, Cu, Al, Ta, Ru, Ir, or Co) or metal nitride (e.g., nitride of Ti, Mo, W, Cu, Al, Ta, Ru, Ir, or Co).

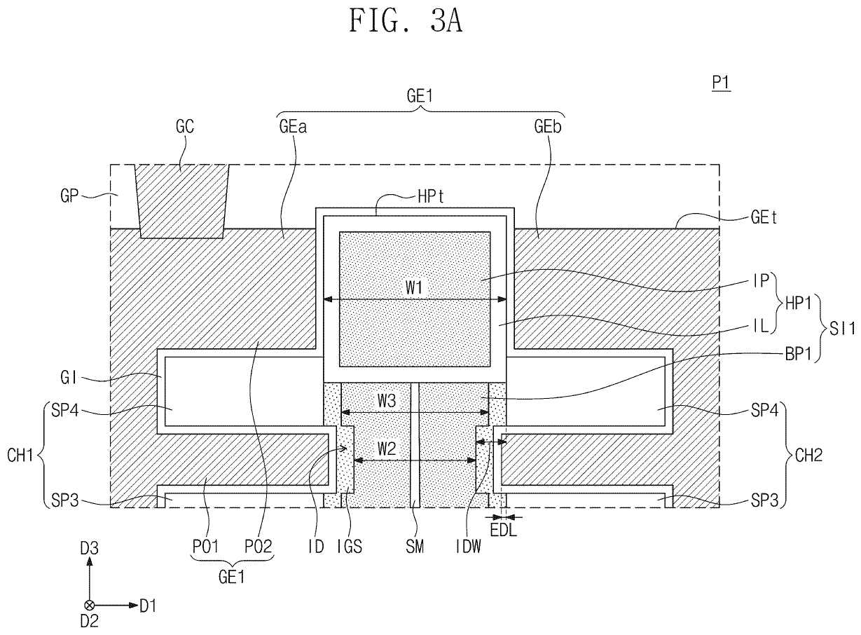

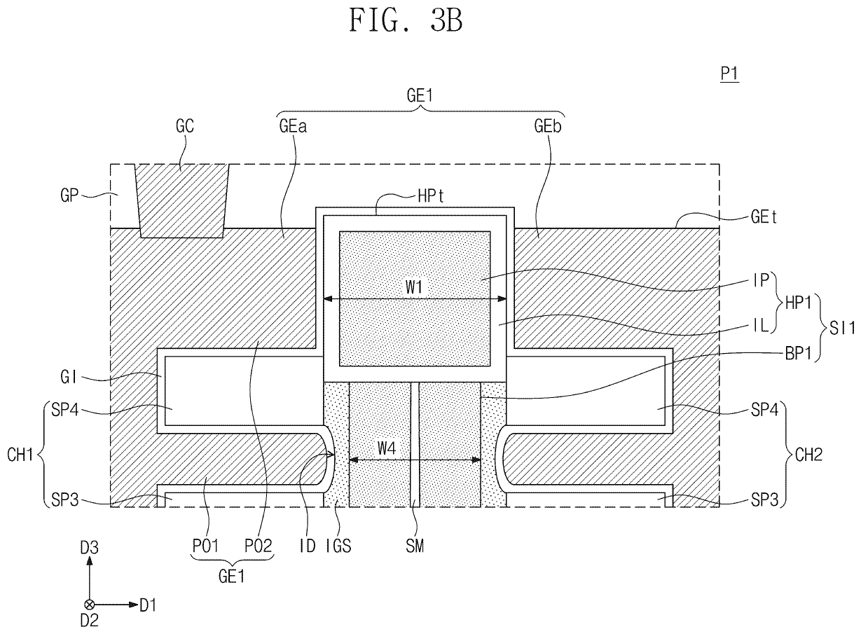

FIG. 3A and FIG. 3B are views for explaining a separation pattern of a semiconductor device according to embodiments of the inventive concept, and are enlarged views of region ‘P1’ of FIG. 2A.

Referring to FIG. 2A and FIG. 3A, the first head portion HP1 of the first separation pattern SI1 may include an insulating pattern IP and an insulating layer IL. The insulating layer IL may be formed on the insulating pattern IP. The insulating layer IL may surround the insulating pattern IP. The insulating layer IL may surround the insulating pattern IP with a uniform thickness. The insulating pattern IP may be spaced apart from other adjacent components by the insulating layer IL. The insulating pattern IP and the insulating layer IL may include different materials and may have different etch selectivity. Accordingly, the insulating layer IL may inhibit or prevent the insulating pattern IP from being unintentionally removed during an etching process. That is, the insulating layer IL may function as an etch stop layer. For example, the insulating pattern IP may include silicon nitride, and the insulating layer IL may include silicon oxycarbide (SiOC). The first head portion HP1 may have a first width W1 in the first direction D1. The first width W1 may be about 1 nanometer (nm) to about 30 nm.

The first head portion HP1 may be in contact with a portion of the fourth semiconductor patterns SP4 of the first and second channel patterns CH1 and CH2. More specifically, the insulating layer IL of the first head portion HP1 may be in contact with a side of the fourth semiconductor patterns SP4. For example, at least a portion of the first head portion HP1 may be disposed between, and may be in contact with the uppermost semiconductor patterns among the plurality of semiconductor patterns of the first and second channel patterns CH1 and CH2. For example, a lower surface of the first head portion HP1 may be disposed at a level below an upper side of the fourth semiconductor patterns SP4.

The first body portion BP1 of the first separation pattern SI1 may have indent regions ID on a side thereof. For example, the indent regions ID may be regions recessed from the side of the first body portion BP1. Accordingly, the side of the first body portion BP1 may have a step. The indent regions ID may be disposed between the third and fourth semiconductor patterns SP3 and SP4 of the first and second channel patterns CH1 and CH2. The indent regions ID may be spaced apart from the third and fourth semiconductor patterns SP3 and SP4 in the third direction D3. That is, the indent regions ID may not horizontally overlap the first to fourth semiconductor patterns SP1, SP2, SP3, and SP4 of the first and second channel patterns CH1 and CH2. Each of the indent regions ID may have a depth IDW in the first direction D1. For example, the depth IDW of each of the indent regions ID may be a distance from a bottom surface of the indent regions ID to a side of the adjacent third and fourth semiconductor patterns SP3 and SP4. The depth IDW of each of the indent regions ID may be about 20 nm or less.

The first body portion BP1 may have a second width W2 in the first direction D1 between opposing indent regions ID. The first body portion BP1 may have a third width W3 in the first direction D1 between the fourth semiconductor patterns SP4 or the third semiconductor patterns SP3 of the first and second channel patterns CH1 and CH2. The second width W2 may be smaller than the third width W3. Additionally, each of the second width W2 and the third width W3 may be smaller than the first width W1 of the first head portion HP1. That is, the first head portion HP1 may have a larger horizontal size than the first body portion BP1. The first width W1 may be equal to a distance between the fourth semiconductor patterns SP4 or the third semiconductor patterns SP3 of the first and second channel patterns CH1 and CH2.

Inner gate spacers IGS may be disposed between the first to fourth semiconductor patterns SP1, SP2, SP3, and SP4 of the first and second channel patterns CH1 and CH2 and the first body portion BP1. The inner gate spacers IGS may be disposed in the indent regions ID. For example, the inner gate spacers IGS may cover a side surface of the first body portion BP1 with a uniform thickness. For example, the inner gate spacers IGS may include silicon oxide and a low-k material. In this specification, a low dielectric constant material may be a material that has a lower dielectric constant than silicon oxide.

Due to the indent regions ID of the first body portion BP1, the inner electrodes PO1 of the first gate electrode GE1 may be closer to the first body portion BP1 than the third and four semiconductor patterns SP3 and SP4 of the first and second channel patterns CH1 and CH2. That is, a side of the inner electrodes PO1 adjacent to the first body portion BP1 may be closer to the first body portion BP1 than a side of the third and fourth semiconductor patterns SP3 and SP4 adjacent to the first body portion BP1. Accordingly, a length of each of the inner electrodes PO1 in the first direction D1 may be greater than a length of each of the third and fourth semiconductor patterns SP3 and SP4 in the first direction D1. Further, a length of the third and fourth semiconductor patterns SP3 and SP4 that vertically overlap the inner electrodes PO1 may increase. For example, a distance EDL between a side of the inner electrodes PO1 adjacent to the first body portion BP1 and a side of the third and fourth semiconductor patterns SP3 and SP4 adjacent to the first body portion BP1 may be about 7 nm or less.

Additionally, the first gate electrode GE1 may include a first portion GEa and a second portion GEb. The first portion GEa may be disposed on the first channel pattern CH1, and the second portion GEb may be disposed on the second channel pattern CH2. For example, the first portion GEa may surround three sides of each of the first to fourth semiconductor patterns SP1, SP2, SP3, and SP4 of the first channel pattern CH1, and the second portion GEb may surround three sides of each of the first to fourth semiconductor patterns SP1, SP2, SP3, and SP4 of the second channel pattern CH2. An upper surface GEt of the first gate electrode GE1 may be lower than an upper surface HPt of the first head portion HP1 of the first separation pattern SI1. For example, a portion of a side surface of the first separation pattern SI1 may extend from the upper surface GEt of the first gate electrode GE1 to the upper surface HPt of the first head portion HP1. The first portion GEa and the second portion GEb of the first gate electrode GE1 may be spaced apart from each other in the first direction D1 by the first separation pattern SI1. Accordingly, the first portion GEa and the second portion GEb of the first gate electrode GE1 may be electrically insulated from each other. Accordingly, the first channel pattern CH1 and the second channel pattern CH2 adjacent to the first separation pattern SI1 may constitute different logic transistors.

A gate insulating layer GI may be disposed between the first portion GEa of the first gate electrode GE1 and the first channel pattern CH1, and between the second portion GEb of the first gate electrode GE1 and the second channel pattern CH2. The gate insulating layer GI may extend between the first gate electrode GE1 and the first and second channel patterns CH1 and CH2, and between the first gate electrode GE1 and the inner gate spacers IGS. Additionally, the gate insulating layer GI may extend between the first gate electrode GE1 and the first and second channel patterns CH1 and CH2, and between the first gate electrode GE1 and the first head portion HP1. The gate insulating layer GI may cover a portion the first head portion HP1 exposed above the first gate electrode GE1, including the upper surface HPt. For example, the gate insulating layer GI may cover a portion of a side surface of the first separation pattern SI1 extending from the first gate electrode GE1 to the upper surface HPt.

Referring to FIG. 2A and FIG. 3B, the first body portion BP1 of the first separation pattern SI1 may not have the indent regions ID of FIG. 3A. For example, a side surface of the first body portion BP1 may not have a step. For example, a side surface of the first body portion BP1 may have a linear shape in the third direction D3. The first body portion BP1 may have a fourth width W4 in the first direction D1. The fourth width W4 may be larger than the second width W2 and smaller than the third width W3 in FIG. 3A. The fourth width W4 may be smaller than the first width W1 of the first head portion HP1. That is, the first body portion BP1 may have a smaller horizontal size than the first head portion HP1.

Inner gate spacers IGS may be disposed on opposing sides of the first body portion BP1. Each of the inner gate spacers IGS may have indent regions ID on a side thereof. The indent regions ID may be regions recessed from an outer surface of the inner gate spacers IGS toward the first separation pattern SI1. Due to the indented regions ID, each of the inner gate spacers IGS may not have a uniform thickness. For example, the inner gate spacers IGS may have a thinner thickness at a region between the inner electrodes PO1 of the first gate electrode GE1 and the first body portion BP1 than between the third and fourth semiconductor pattern SP3 and SP4 and the first body portion BP1.

Due to the indent regions ID of the inner gate spacers IGS, the inner electrodes PO1 of the first gate electrode GE1 may be closer to the first body portion BP1 than the third and fourth semiconductor patterns SP3 and SP4 of the first and second channel patterns CH1 and CH2. That is, a side of the inner electrodes PO1 adjacent to the first body portion BP1 may be closer to the first body portion BP1 than a side of the third and fourth semiconductor patterns SP3 and SP4 adjacent to the first body portion BP1. Accordingly, a length of each of the inner electrodes PO1 in the first direction D1 may be greater than a length of each of the third and fourth semiconductor patterns SP3 and SP4 in the first direction D1. Further, a length of the third and fourth semiconductor patterns SP3 and SP4 that vertically overlap the inner electrodes PO1 may increase.

The gate insulating layer GI between the first and second channel patterns CH1 and CH2 and the first gate electrode GE1 may extend between the inner electrodes PO1 of the first gate electrode GE1 and the inner gate spacers IGS. For example, the gate insulating layer GI may cover the indented regions ID of the inner gate spacers IGS with a uniform thickness.

Referring again to FIG. 2A, FIG. 3A, and FIG. 3B, the first head portion HP1 of the first separation pattern SI1 may have a larger horizontal size than the first body portion BP1. In a process of manufacturing a semiconductor device, the first head portion HP1 may inhibit or prevent the first body portion BP1 and a seam SM inside the first body portion BP1 from being exposed to the outside. The first body portion BP1 may be protected from being unintentionally removed by the first head portion HP1. In addition, a distance between the first portion GEa and the second portion GEb of the first gate electrode GE1 may be secured. Further, an electrical short circuit between the first portion GEa and the second portion GEb of the first gate electrode GE1 may be inhibited or prevented. Accordingly, durability of the semiconductor device may be increased.

The inner gate spacers IGS including an insulating material may be disposed between the first to fourth semiconductor patterns SP1, SP2, SP3, and SP4 of the first and second channel patterns CH1 and CH2 and the first separation pattern SI1. The inner gate spacers IGS may inhibit or prevent leakage current occurring from the first to fourth semiconductor patterns SP1, SP2, SP3, and SP4. In addition, a horizontal length of each of the inner electrodes PO1 of the first and second gate electrodes GE1 and GE2 may be greater than a horizontal length of each of the first to fourth semiconductor patterns SP1, SP2, SP3, and SP4 of the first and second channel patterns CH1 and CH2. Further, a length of the first to fourth semiconductor patterns SP1, SP2, SP3, and SP4 that vertically overlap the inner electrodes PO1 may increase. Accordingly, electrical characteristics of the semiconductor device may be improved.

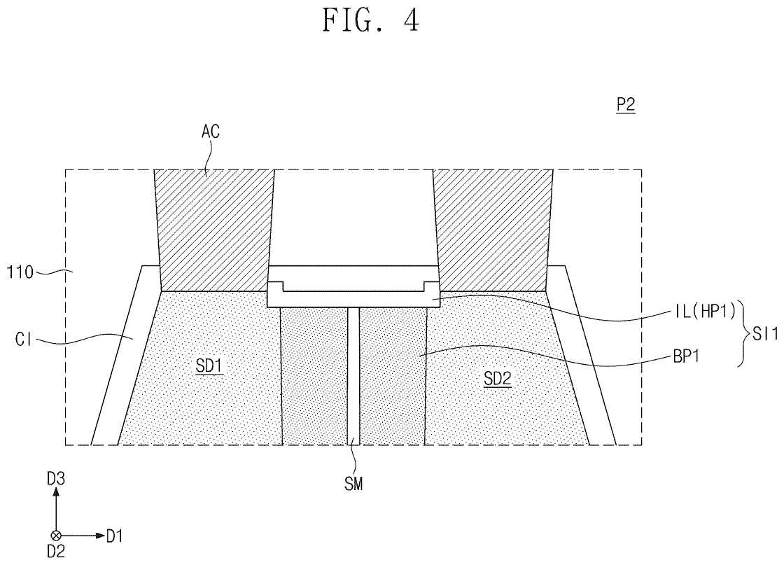

FIG. 4 is a view for explaining a separation pattern of a semiconductor device according to embodiments of the inventive concept, and is an enlarged view of region ‘P2’ of FIG. 2D.

Referring to FIG. 2B and FIG. 4, a portion of the first separation pattern SI may be provided between the first and second source/drain patterns SD1 and SD2 adjacent to each other in the first direction D1. For example, the first body portion BP1 of the first separation pattern SI1 may be disposed between the first and second source/drain patterns SD1 and SD2 that are adjacent to each other. A portion of the insulating layer IL of the first head portion HP1 may be disposed on the first body portion BP1. A portion of the insulating layer IL may extend onto side surfaces of the active contacts AC on the first body portion BP1. For example, a width of the insulating layer IL may be greater than a width of the first body portion BP1. For example, a portion of the insulating layer IL may have a U-shape. In other words, the first separation pattern SI1 between the first and second source/drain patterns SD1 and SD2 adjacent to each other in the first direction D1 may not include the insulating pattern IP of the first head portion HP1 described with reference to FIG. 3A and FIG. 3B. According to an embodiment, a portion of the insulating layer IL may have a bar shape parallel to the first direction D1.

A portion of the insulating layer IL may cover an upper surface of the first body portion BP1 and may cap the seam SM inside the first body portion BP1. The insulating layer IL and the first body portion BP1 may include different insulating materials and may have different etch selectivity. For example, the insulating layer IL may inhibit or prevent the first body portion BP1 from being unintentionally removed during an etching process. That is, as the insulating layer IL functions as an etch stop layer, a height of the first body portion BP1 in the third direction D3 may be maintained during the manufacturing process of the semiconductor device.

Additionally, the active contacts AC connected to each of the first and second source/drain patterns SD1 and SD2 may be formed in a self-aligned manner using a portion of the insulating layer IL. The active contacts AC may be spaced apart from each other in the first direction D1 by a portion of the insulating layer IL. Accordingly, an electrical short may not occur between the active contacts AC adjacent to each other in the first direction D1. Accordingly, electrical characteristics of the semiconductor device may be improved.

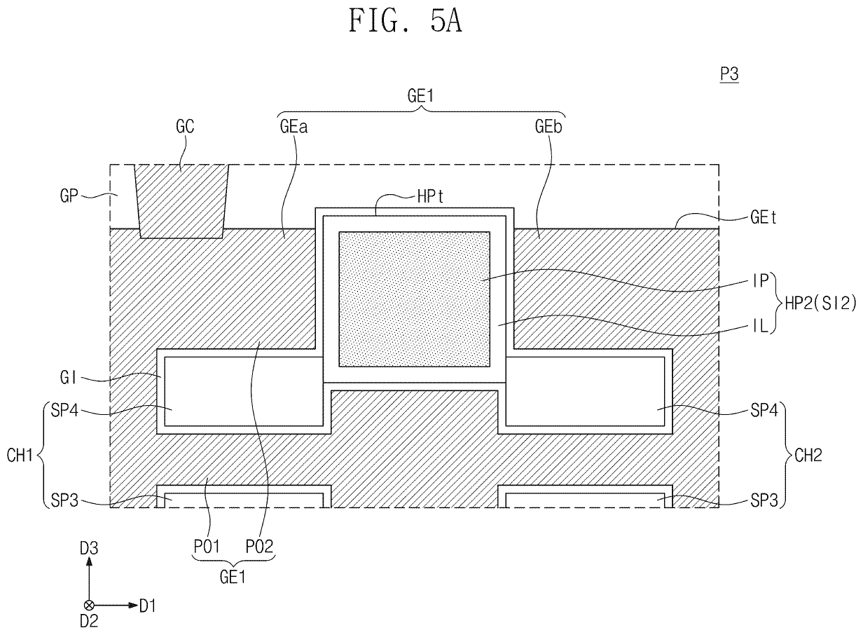

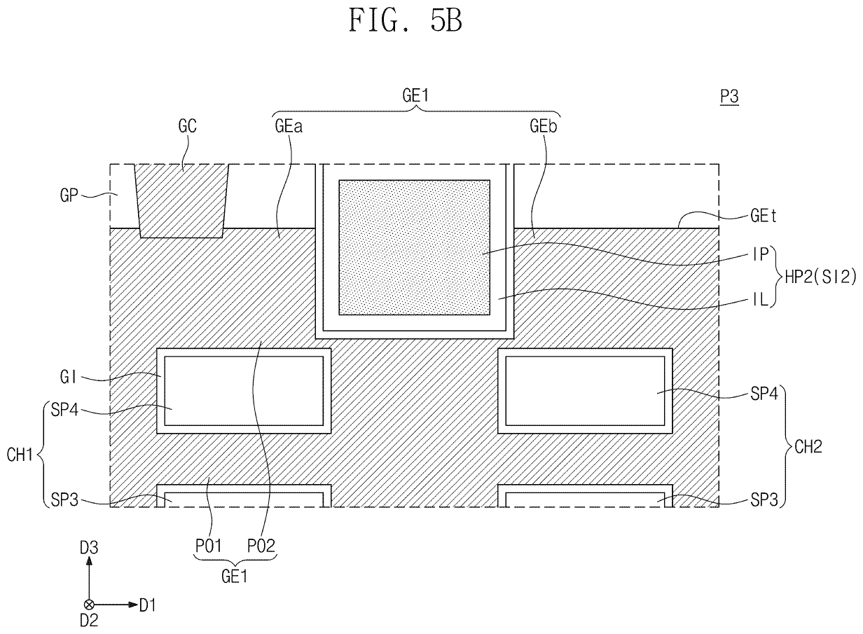

FIG. 5A and FIG. 5B are views for explaining the separation pattern of a semiconductor device according to embodiments of the inventive concept, and are enlarged views of region ‘P3’ of FIG. 2D.

Referring to FIG. 2D and FIG. 5A, the second head portion HP2 of the second separation pattern SI2 may include an insulating pattern IP and an insulating layer IL. The insulating layer IL may surround the insulating pattern IP. The insulating layer IL may surround the insulating pattern IP with a uniform thickness. The insulating layer IL and the insulating pattern IP may include different insulating materials and have different etch selectivity. That is, the second head portion HP2 may be substantially the same as the first head portion HP1 described with reference to FIG. 3A and FIG. 3B.

The second head portion HP2 may be in contact with a portion of the fourth semiconductor patterns SP4 of the first and second channel patterns CH1 and CH2. More specifically, the insulating layer IL of the second head portion HP2 may be in contact with a side of the fourth semiconductor patterns SP4. For example, the second head portion HP2 may be disposed between, and in contact with, the uppermost semiconductor patterns among the plurality of semiconductor patterns of the first and second channel patterns CH1 and CH2.

The second body portion BP2 of the second separation pattern SI2 may not be in contact with the second head portion HP2. That is, the second head portion HP2 may be spaced apart from the second body portion BP2 in the third direction D3. For example, the second body portion BP2 may not be connected to the first and second channel patterns CH1 and CH2.

The first gate electrode GE1 may include a first portion GEa on the first channel pattern CH1 and a second portion GEb on the second channel pattern CH2. The first portion GEa and the second portion GEb of the first gate electrode GE1 may be connected to each other between the second head portion HP2 and the second body portion BP2. As the first gate electrode GE1 may be disposed between the first and second channel patterns CH1 and CH2, the first gate electrode GE1 may surround each of the first to fourth semiconductor patterns SP1, SP2, SP3, and SP4 of the first and second channel patterns CH1 and CH2. As the first portion GEa and the second portion GEb of the first gate electrode GE1 may not be spaced apart from each other in the first direction D1, the first and second channel patterns CH1 and CH2 adjacent to the second separation pattern SI2 may constitute one logic transistor.

The gate insulating layer GI may be disposed between the first gate electrode GE1 and the first and second channel patterns CH1 and CH2. The gate insulating layer GI may surround the sides of each of the first to fourth semiconductor patterns SP1, SP2, SP3, and SP4 of the first and second channel patterns CH1 and CH2. The gate insulating layer GI may extend between the first gate electrode GE1 and the first and second channel patterns CH1 and CH2 and between the first gate electrode GE1 and the second head portion HP2. The gate insulating layer GI may cover the upper surface HPt of the second head portion HP2.

Referring to FIG. 2D and FIG. 5B, the second head portion HP2 of the second separation pattern SI2 may be spaced apart from the first and second channel patterns CH1 and CH2. The second head portion HP2 may be spaced apart from the fourth semiconductor patterns SP4 of the first and second channel patterns CH1 and CH2 and the gate insulating layer GI surrounding the fourth semiconductor patterns SP4. For example, the second head portion HP2 may be positioned at a higher level than the uppermost semiconductor pattern among the plurality of semiconductor patterns of the first and second channel patterns CH1 and CH2. For example, a lower surface of the second head portion HP2 may be positioned at a higher level than the uppermost semiconductor pattern among the plurality of semiconductor patterns of the first and second channel patterns CH1 and CH2.

The gate insulating layer GI may be disposed between the first gate electrode GE1 and the first and second channel patterns CH1 and CH2 and between the first gate electrode GE1 and the second head portion HP2. The gate insulating layer GI may surround the second head portion HP2 while being in contact with the insulating layer IL of the second head portion HP2. The gate insulating layer GI may not extend between the first gate electrode GE1 and the first and second channel patterns CH1 and CH2 and between the first gate electrode GE1 and the second head portion HP2. That is, portions of the gate insulating layer GI surrounding the first and second channel patterns CH1 and CH2 and the gate insulating layer GI surrounding the second head portion HP2 may be spaced apart from each other.

Referring again to FIG. 2D, FIG. 5A, and FIG. 5B, the second head portion HP2 and the second body portion BP2 of the second separation pattern SI2 may be spaced apart from each other. The first portion GEa and the second portion GEb of the first gate electrode GE1 may be connected to each other between the second head portion HP2 and the second body portion BP2. Further, the first gate electrode GE1 may surround the sides of each of the first to fourth semiconductor patterns SP1, SP2, SP3, and SP4 of the first and second channel patterns CH1 and CH2. That is, a channel length of the logic transistor composed of the first and second channel patterns CH1 and CH2 adjacent to the second separation pattern SI2 may increase. Accordingly, electrical characteristics of the semiconductor device may be improved.

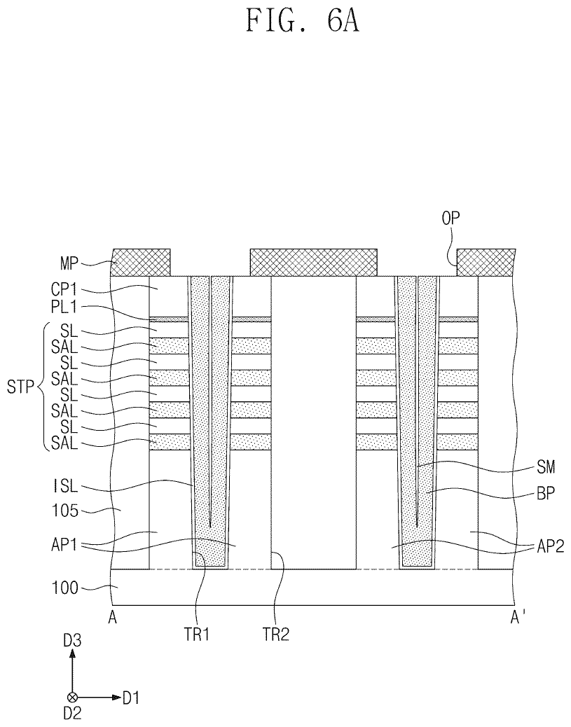

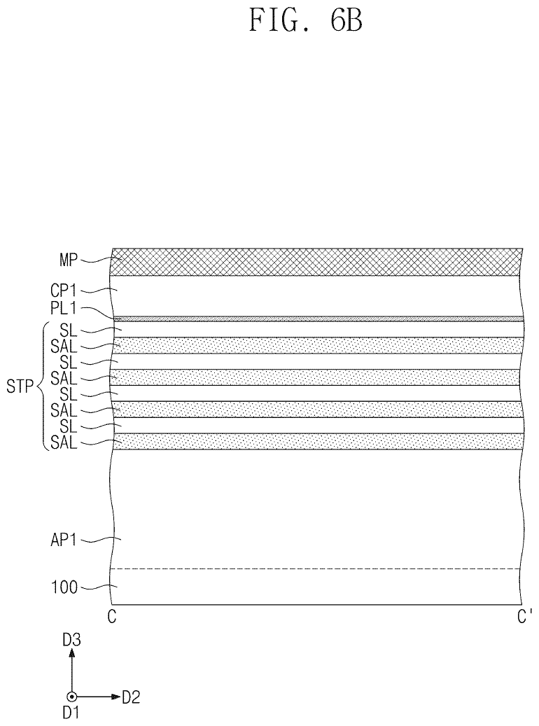

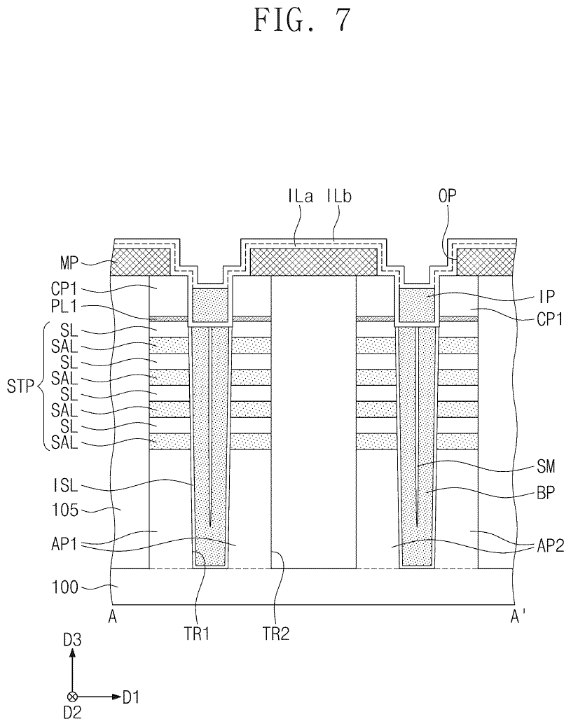

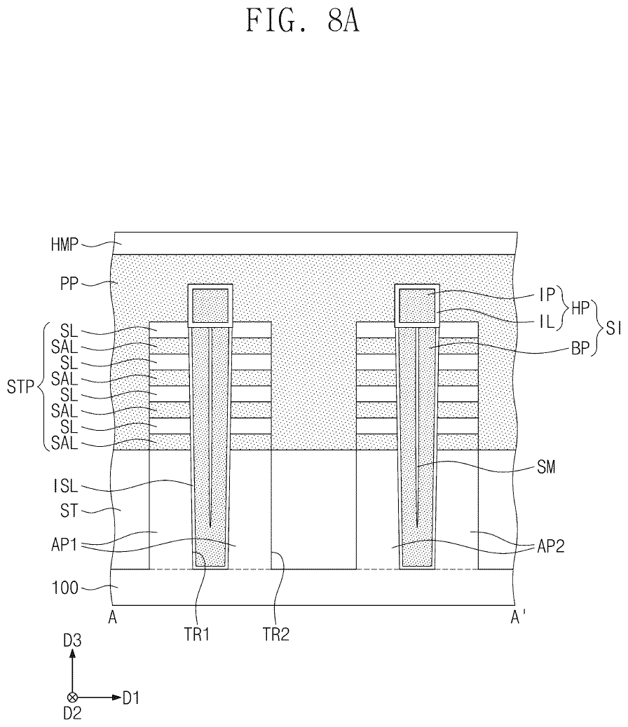

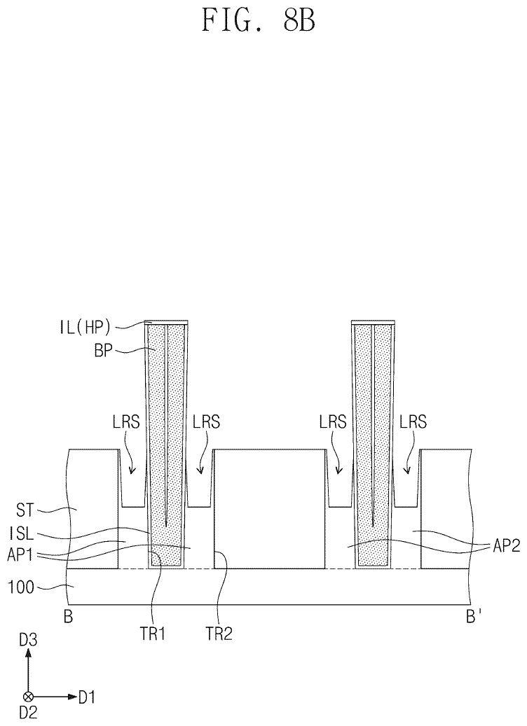

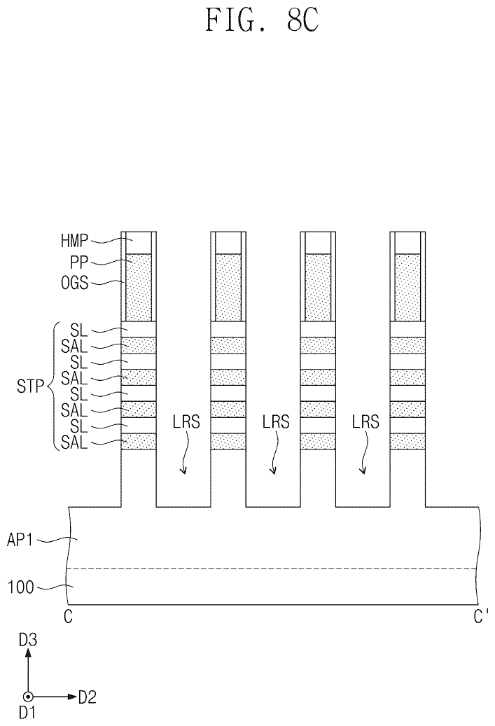

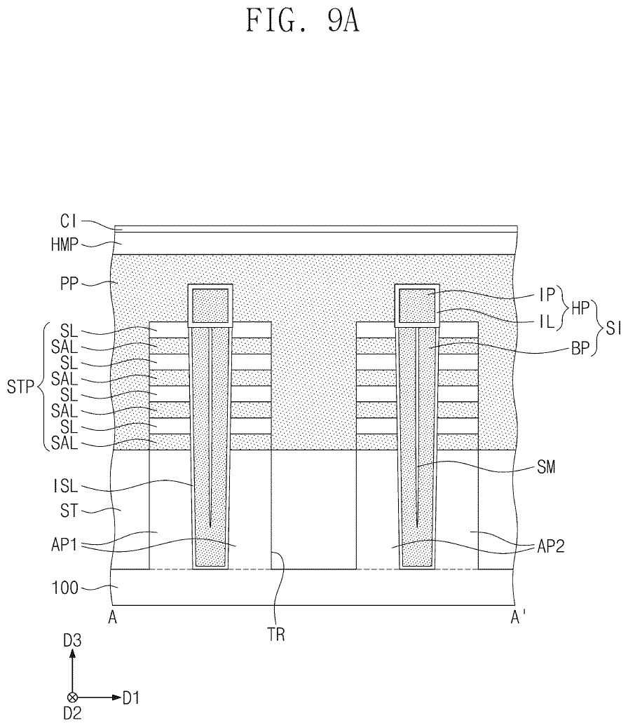

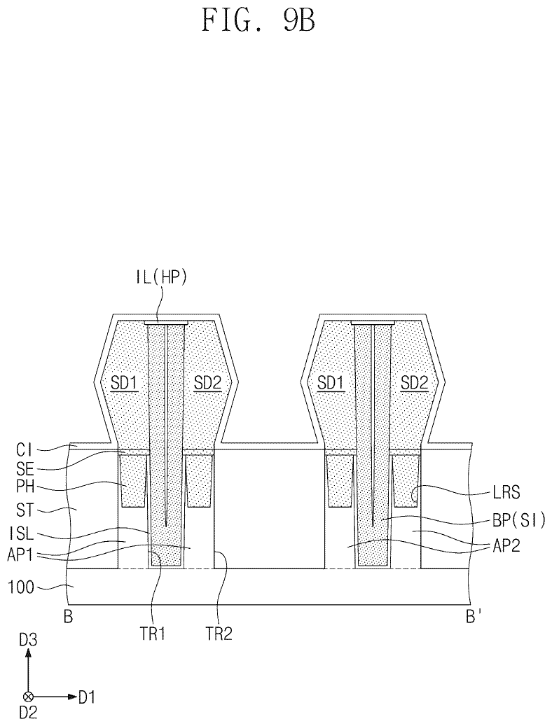

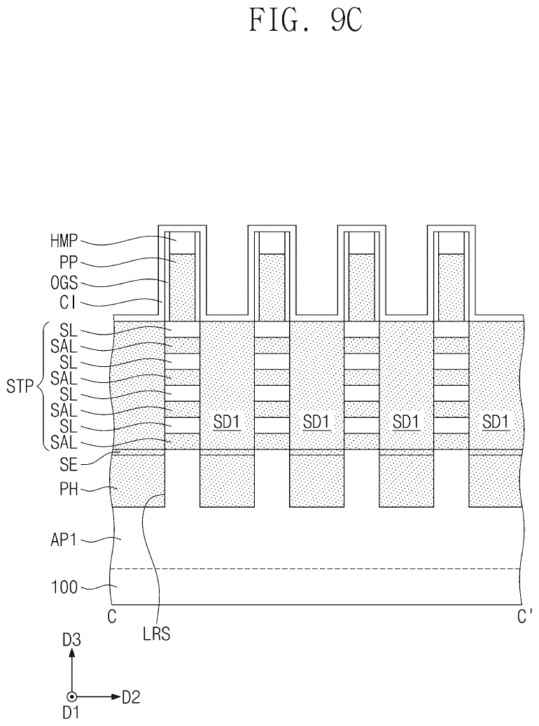

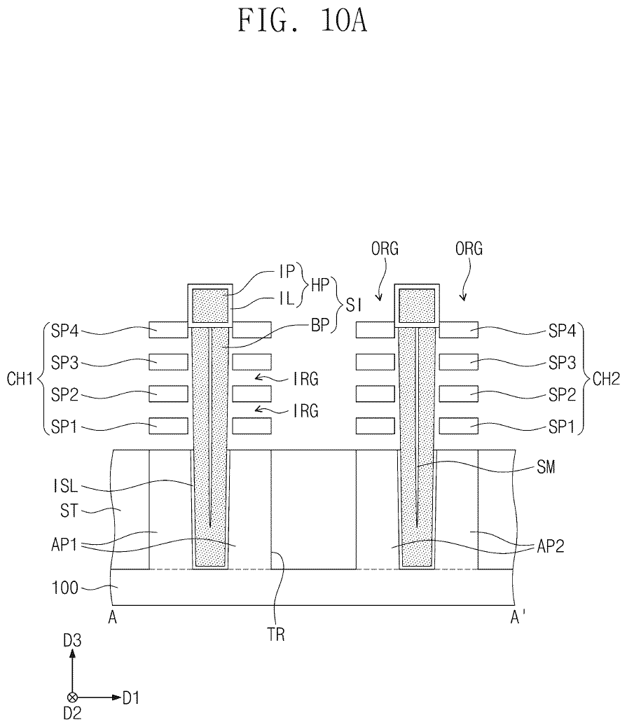

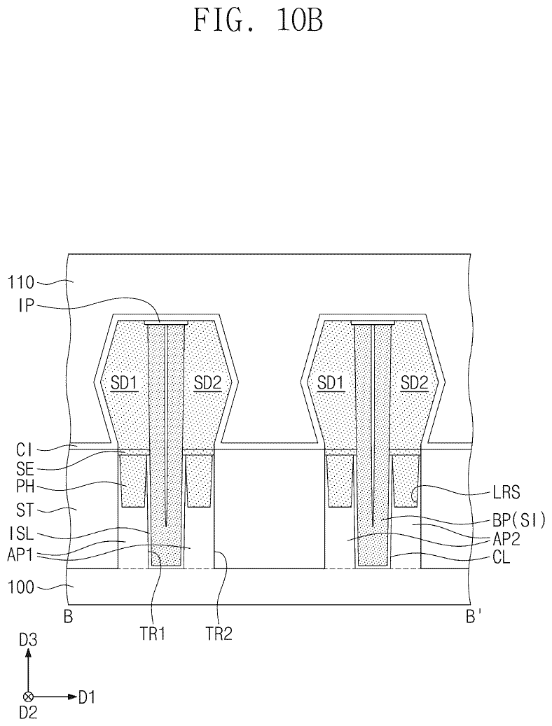

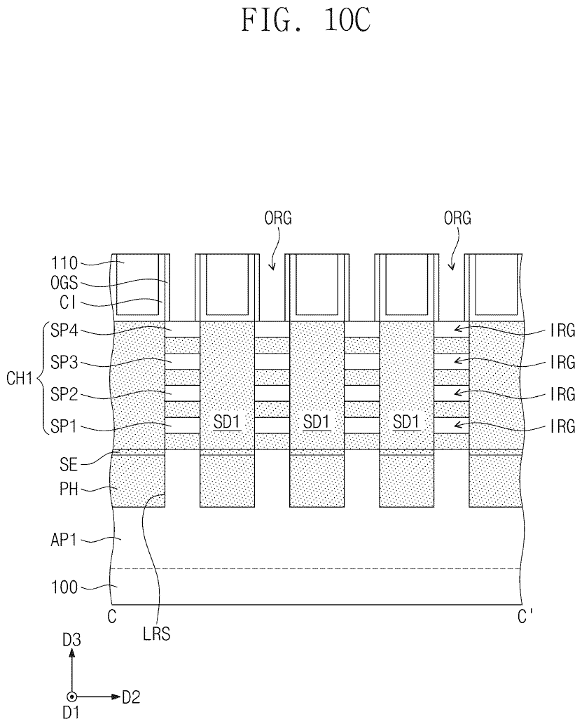

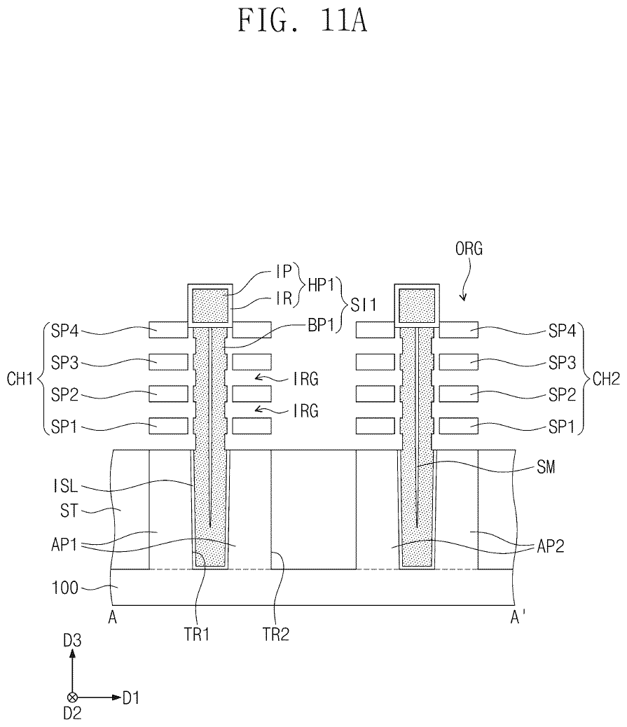

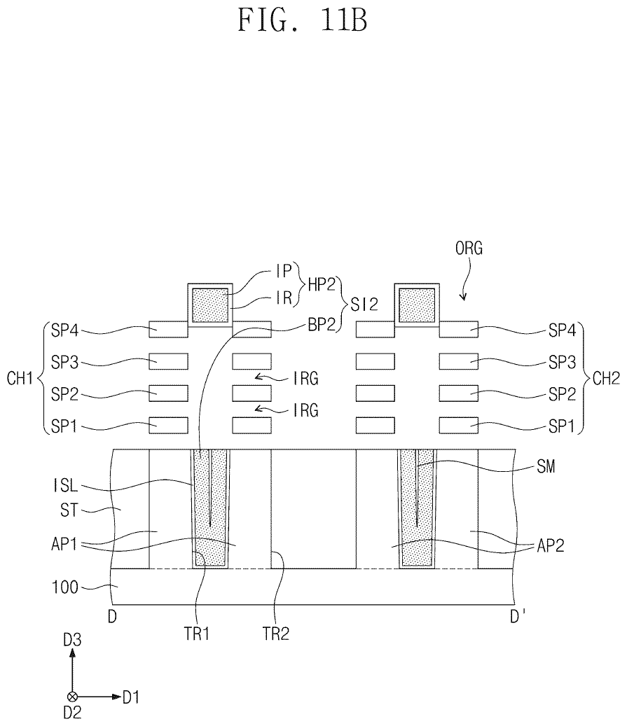

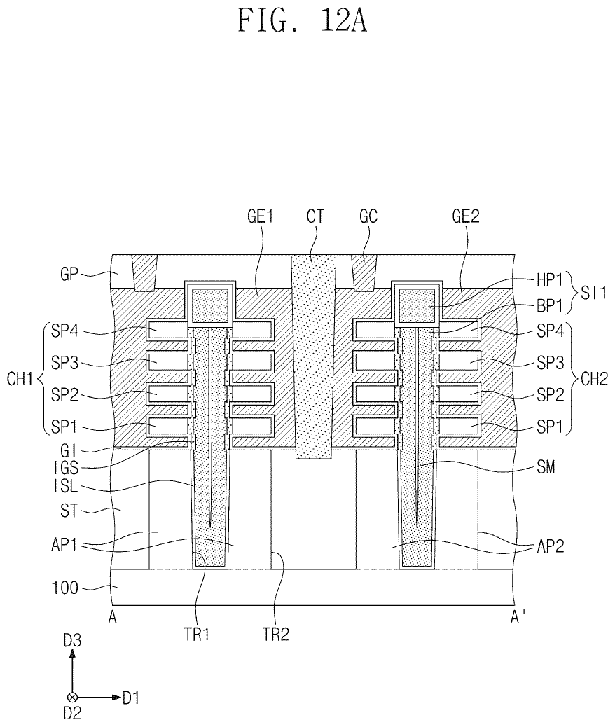

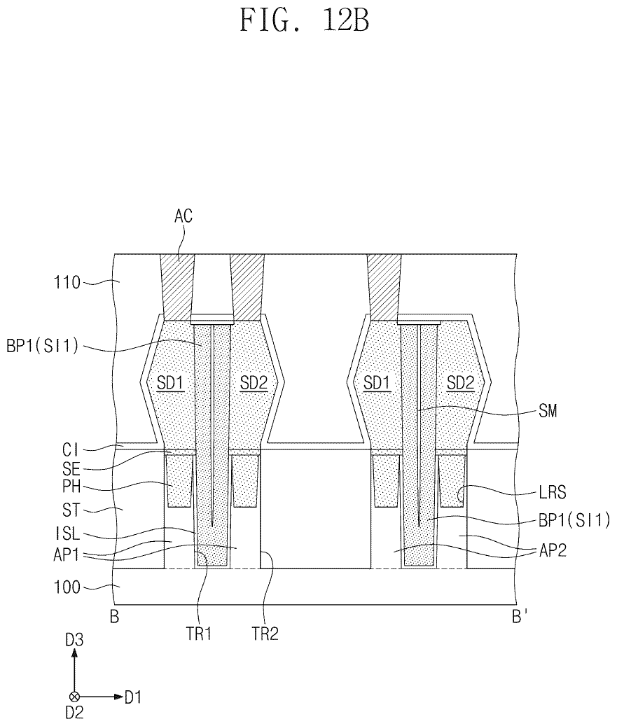

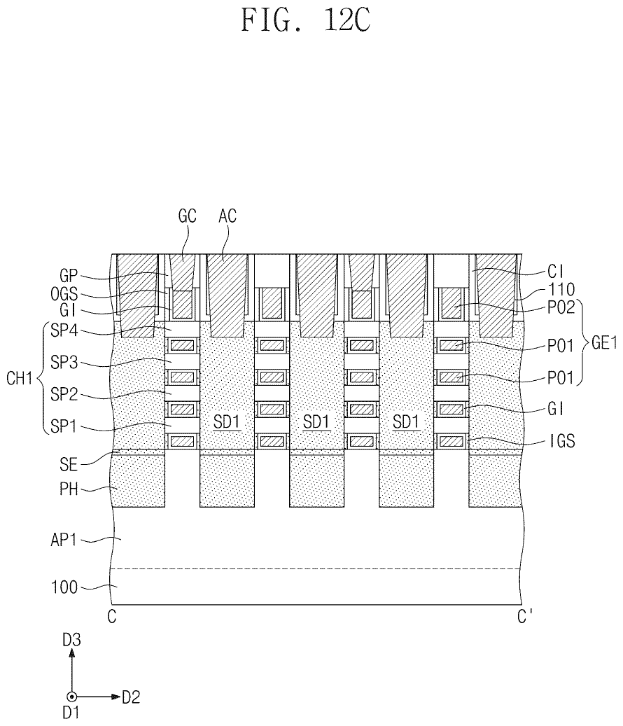

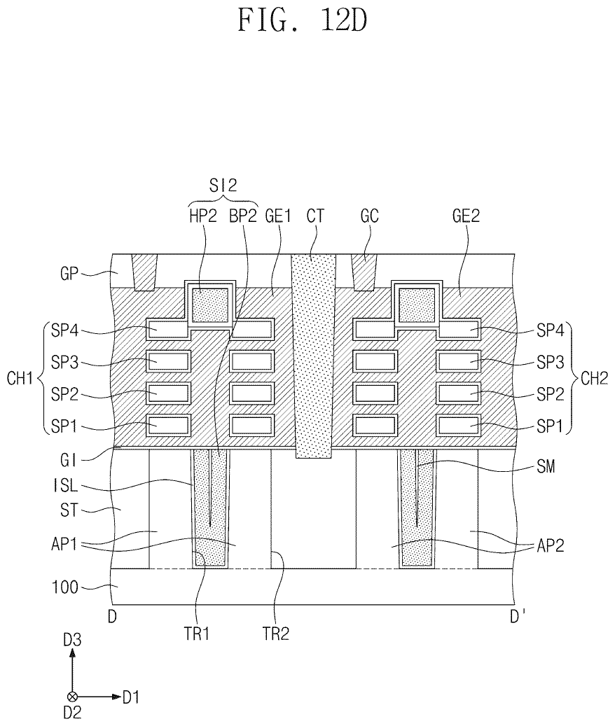

FIGS. 6A to 12D are views for explaining a method of manufacturing a semiconductor device according to embodiments of the inventive concept, FIG. 6A, FIG. 7, FIG. 8A, FIG. 9A, FIG. 10A, FIG. 11A, and FIG. 12A are views taken along line A-A′ of FIG. 1, FIG. 8B, FIG. 9B, FIG. 10B, and FIG. 12B are views taken along line B-B′ of FIG. 1, FIG. 6B, FIG. 8C, FIG. 9C, and FIG. 10C, and FIG. 12C are views taken along line C-C′ of FIG. 1, and FIG. 11B and FIG. 12D are views taken along line D-D′ of FIG. 1.

Referring to FIG. 6A and FIG. 6B, a substrate 100 may be provided. For example, the substrate 100 may be a substrate containing silicon, germanium, or silicon-germanium, or a compound semiconductor substrate.

Stacked patterns STP, a first protective layer PL1, and a first capping pattern CP1 may be formed sequentially on the substrate 100. The stacked patterns STP may include semiconductor layers SL and sacrificial layers SAL alternately stacked in the third direction D3. For example, a sacrificial layer SAL may be formed on the substrate 100 followed by a semiconductor layer SL. The sacrificial layers SAL may include a material that has an etch selectivity with the semiconductor layers SL. In a process of removing the sacrificial layers SAL, the semiconductor layers SL may not be removed or may be removed in small amounts. For example, the semiconductor layers SL may include one of silicon, germanium, or silicon-germanium, and the sacrificial layers SAL may include another one of silicon, germanium, or silicon-germanium. The first protective layer PL1 may include an insulating material. The first capping pattern CP1 may include silicon-germanium.

Forming the stacked patterns STP, the first protective layer PL1, and the first capping pattern CP1 may include alternately forming semiconductor layers SL and sacrificial layers SAL on the substrate 100, forming a first protective layer PL1 and a first capping pattern CP1, and performing a patterning process. Due to a patterning process, an upper portion of the substrate 100 may be removed. Further, first and second trenches TR1 and TR2 defining first and second active patterns AP1 and AP2 may be formed. Each of the first and second active patterns AP1 and AP2 may extend in the second direction D2.

Thereafter, an insulating shell layer ISL and a body portion BP may be sequentially formed in the first trenches TR1. Forming the insulating shell layer ISL and the body portion BP may include forming the insulating shell layer ISL on the surface of the substrate 100, filling an insulating material in the first trenches TR1, and performing a planarization process on the insulating shell layer ISL and the insulating material to expose the first capping pattern CP1. The insulating shell layer ISL may be formed to a uniform thickness on the entire surface of the substrate 100. Due to a large aspect ratio of the first trenches TR1, a seam SM may be formed inside the body portion BP. The seam SM inside the body portion BP may have a shape extending in the third direction D3 and may be exposed to the outside. For example, the insulating shell layer ISL may include silicon oxide, and the body portion BP may include silicon nitride.

A device isolation layer 105 may be formed in the second trenches TR2. The device isolation layer 105 may be disposed in the second trenches TR2. The device isolation layer 105 may fill the second trenches TR2. As the second trenches TR2 may have a relatively smaller aspect ratio than the first trenches TR1, a seam or void may not be formed inside the device isolation layer 105. An upper surface of the device isolation layer 105 may be coplanar with an upper surface of the first capping pattern CP1.

A mask pattern MP may be formed on the device isolation layer 105 and the first capping pattern CP1. The mask pattern MP may have an opening OP. The opening OP of the mask pattern MP may expose an upper surface of the body portion BP and a portion of an upper surface of the first capping pattern CP1.

Referring to FIG. 7, an etching process using the mask pattern MP may be performed. Portions of the insulating shell ISL and body portion BP may be removed through an etching process. Accordingly, upper surfaces of the insulating shell layer ISL and the body portion BP may be lowered. For example, the upper surface of the body portion BP may be disposed lower than an upper surface of the uppermost semiconductor layer among the semiconductor layers SL of the stacked patterns STP. As the first capping pattern CP1 may have an etch selectivity with respect to the body portion BP and the insulating shell layer ISL, the first capping pattern CP1 may not be removed through the etching process.

Thereafter, a first preliminary insulating layer ILa, an insulating pattern IP, and a second preliminary insulating layer ILb may be formed sequentially. The first preliminary insulating layer ILa may be formed on the entire surface of the substrate 100 to have a uniform thickness. The first preliminary insulating layer ILa may cover the mask pattern MP, the upper surface of the body portion BP, and side surfaces of the first capping pattern CP1. The first preliminary insulating layer ILa may cover the upper surface of the body portion BP. The first preliminary insulating layer ILa may cap the seam SM inside the body portion BP. An insulating pattern IP may be formed on the first preliminary insulating layer ILa. The insulating pattern IP may be formed on the first preliminary insulating layer ILa to fill a space where a portion of the body portion BP has been removed, and the second preliminary insulating layer ILb may be formed on the entire surface of the substrate 100 with a uniform thickness. The second preliminary insulating layer ILb may cover the first preliminary insulating layer ILa and the insulating pattern IP. Accordingly, the insulating pattern IP may be surrounded by the first preliminary insulating layer ILa and the second preliminary insulating layer ILb.

The first preliminary insulating layer ILa and the second preliminary insulating layer ILb may include substantially the same material. Accordingly, an interface between the first preliminary insulating layer ILa and the second preliminary insulating layer ILb may not be distinguished. The insulating pattern IP may include a material different from the first preliminary insulating layer ILa and the second preliminary insulating layer ILb. For example, the first and second preliminary insulating layers ILa and ILb may include silicon oxycarbide (SiOC), and the insulating pattern IP may include silicon nitride.

Referring to FIG. 8A, FIG. 8B, and FIG. 8C, a planarization process may be performed on the entire surface of the substrate 100. Due to a planarization process, portions of the mask pattern MP and the first and second preliminary insulating layers ILa and ILb may be removed, and the device isolation layer 105 may be exposed again. Further, an insulating layer IL surrounding the insulating pattern IP may be formed from the first and second preliminary insulating layers ILa and ILb. The head portion HP including the insulating pattern IP and the insulating layer IL may be formed on the body portion BP, and a separation pattern SI including the body portion BP and the head portion HP may be formed.

The head portion HP of the separation pattern SI may have a larger horizontal size than the body portion BP, as described with reference to FIG. 3A and FIG. 3B. An upper end of the body portion BP may not be exposed to the outside by the head portion HP. In a semiconductor process, the head portion HP may inhibit or prevent the body portion BP from being unintentionally removed. That is, the head portion HP may protect the body portion BP. Accordingly, a distance between gate electrodes, and which are formed to be spaced apart from each other based on the separation pattern SI, may be secured. Accordingly, durability and electrical characteristics of the semiconductor device may be improved.

After the separation pattern SI is formed, the first capping pattern CP1 and the first protective layer PL1 may be removed. A portion of the device isolation layer 105 may be removed until an upper surface of the device isolation layer 105 is substantially coplanar with upper surfaces of the first and second active patterns AP1 and AP2. Accordingly, a device isolation pattern ST may be formed from the device isolation layer 105.

Thereafter, a plurality of sacrificial patterns PP may be formed on the stacked patterns STP, crossing the stacked patterns STP. Each of the sacrificial patterns PP may be formed in a line shape extending in the first direction D1. Forming the sacrificial patterns PP may include forming a sacrificial layer on the entire surface of the substrate 100, forming hard mask patterns HMP on the sacrificial layer, and patterning the sacrificial layer using the hard mask patterns HMP. For example, the sacrificial layer may include amorphous silicon and/or polysilicon.

A pair of outer gate spacers OGS may be formed on opposing sides of the sacrificial patterns PP. Forming the outer gate spacers OGS may include forming a spacer layer covering the sacrificial patterns PP and the hard mask pattern HMP, and anisotropically etching the spacer layer. For example, the spacer layer may include a single layer or a multilayer layer containing different insulating materials.

Afterwards, an etching process using the outer gate spacers OGS and the hard mask patterns HMP may be performed. An etching process may partially remove the stacked patterns STP and the first and second active patterns AP1 and AP2. Due to an etching process, lower recesses LRS may be formed between the sacrificial patterns PP adjacent to each other in the second direction D2. The stacked patterns STP may extend in the third direction D3 due to the lower recesses LRS.

The head portion HP of the separation pattern SI that is not covered by the sacrificial patterns PP may be partially removed by an etching process using the outer gate spacers OGS and the hard mask patterns HMP. For example, the insulating pattern IP of the head portion HP may be removed, and only a portion of the insulating layer IL may remain on the body portion BP of the separation pattern SI. A portion of the insulating layer IL may function as an etch stop layer to inhibit or prevent the body portion BP from being removed during an etching process. That is, the insulating layer IL of the head portion HP may protect the body portion BP from an etching process.

Referring to FIG. 9A, FIG. 9B, and FIG. 9C, sacrificial contact patterns PH may be formed in the first and second active patterns AP1 and AP2 exposed by the lower recesses LRS. The sacrificial contact patterns PH may be formed in a contact plug shape. The sacrificial contact patterns PH may include a material having an etch selectivity with respect to the first and second active patterns AP1 and AP2. For example, the sacrificial contact patterns PH may be formed through an epitaxial growth process and may include silicon-germanium.

Seed patterns SE and first and second source/drain patterns SD1 and SD2 may be sequentially formed on each of the sacrificial contact patterns PH. The first and second source/drain patterns SD1 and SD2 may be formed through a selective epitaxial growth process using the seed patterns SE as a seed layer. While the first and second source/drain patterns SD1 and SD2 are formed, impurities may be injected in-situ into the first and second source/drain patterns SD1 and SD2. Alternatively, impurities may be injected after the first and second source/drain patterns SD1 and SD2 are formed.

Thereafter, a capping insulating layer CI may be formed on a surface of the substrate 100. For example, the capping insulating layer CI may be formed on the entire surface of the substrate 100. The capping insulating layer CI may cover the hard mask patterns HMP, the first and second source/drain patterns SD1 and SD2, and the device isolation pattern with a uniform thickness.

According to an embodiment, before the first and second source/drain patterns SD1 and SD2 are formed, a portion of the insulating shell layer ISL on a side surface of the body portion BP of the separation pattern SI adjacent to the first and second source/drain patterns SD1 and SD2 may be removed.

Referring to FIG. 10A, FIG. 10B, and FIG. 10C, a first upper insulating layer 110 may be formed on the first and second source/drain patterns SD1 and SD2. The first upper insulating layer 110 may cover the capping insulating layer CI. Thereafter, a planarization process may be performed on the first upper insulating layer 110, which may expose upper surfaces of the sacrificial patterns PP. Through a planarization process, the hard mask patterns HMP on the sacrificial patterns PP may be removed together. Accordingly, an upper surface of the first upper insulating layer 110 may be coplanar with the upper surfaces of the sacrificial patterns PP and the upper surfaces of the outer gate spacers OGS.

Exposed sacrificial patterns PP may be selectively removed. Removing the sacrificial patterns PP may include a wet etching process using an etchant that selectively removes polysilicon. By removing the sacrificial patterns PP, an outer region ORG may be formed. Due to the outer region ORG, the stacked patterns STP may be exposed to the outside.

The sacrificial layers SAL of the stacked patterns STP exposed through the outer region ORG may be selectively removed. The sacrificial layers SAL may be selectively removed to form an inner region IRG. An etching process for selectively removing the sacrificial layers SAL may remove only the sacrificial layers SAL while leaving the semiconductor layers SL intact. An etching process to remove the sacrificial layers SAL may have a high etch rate for silicon-germanium. Accordingly, a channel pattern of a logic transistor may be formed from the semiconductor layers SL. For example, first and second channel patterns CH1 and CH2 including first to fourth semiconductor patterns SP1, SP2, SP3, and SP4 may be formed.

The insulating shell layer ISL on the side surface of the body portion BP of the separation pattern SI may be exposed through the inner region IRG. A portion of the insulating shell ISL exposed through the inner region IRG may be selectively removed, but the insulating shell ISL between the first and second active patterns AP1 and AP2 and the body portion BP may remain intact. Further, the first to fourth semiconductor patterns SP1, SP2, SP3, and SP4 of the first and second channel patterns CH1 and CH2 may be spaced apart from the body portion BP of the separation pattern SI.

Referring to FIG. 11A and FIG. 11B, a portion of the body portion BP of the separation pattern SI exposed through the outer region ORG and the inner region IRG may be selectively removed. Selectively removing a portion of the body portion BP may include a wet etching process using the etch selectivity of the body portion BP and the insulating layer IL of the head portion HP. Through an etching process, only the body portion BP may be selectively removed, and the insulating layer IL of the head portion HP may remain intact. Accordingly, the insulating pattern IP of the head portion HP may be protected by the insulating layer IL.

As described with reference to FIG. 3A, a side surface of the body portion BP may be partially removed so that indent regions ID are formed on the side surface of the body portion BP. As described with reference to FIG. 3B, the side surfaces of the body portion BP may be uniformly removed and an overall width of the body portion BP is reduced. As described with reference to FIG. 5A, a portion of the body portion BP may be completely removed so that the head portion HP and the body portion BP may be spaced apart from each other. Accordingly, a first separation pattern SI1 including the first head portion HP1 and the first body portion BP1 that are in contact with each other and a second separation pattern SI2 including the second head portion HP2 and the second body portion BP2 that are spaced apart from each other may be formed from the separation pattern SI.

Referring to FIG. 12A, FIG. 12B, FIG. 12C, and FIG. 12D, inner gate spacers IGS may be formed on side surface and inner regions IRG of the first body portion BP1 of the first isolation pattern SI1. The inner gate spacers IGS may be disposed between the first to fourth semiconductor patterns SP1, SP2, SP3, and SP4 of the first and second channel patterns CH1 and CH2 and the first body portion BP1 adjacent to each other. The inner gate spacers IGS may not be disposed between the first to fourth semiconductor patterns SP1, SP2, SP3, and SP4 of the first and second channel patterns CH1 and CH2 and the second body portion BP2 that are spaced apart from each other.

The inner gate spacers IGS may include silicon oxide and a low-k material. Further, leakage current occurring from the first to fourth semiconductor patterns SP1, SP2, SP3, and SP4 may be inhibited or prevented. Accordingly, electrical characteristics of the semiconductor device may be improved.

After the inner gate spacers IGS are formed, a gate insulating layer GI may be formed to a uniform thickness in the inner region IRG and the outer region ORG. The gate insulating layer GI may cover the first to fourth semiconductor patterns SP1, SP2, SP3, and SP4 of the first and second channel patterns CH1 and CH2, the first and second separation patterns SI1 and SI2, and the device isolation pattern ST.

First and second gate electrodes GE1 and GE2 may be formed on the gate insulating layer GI. Forming the first and second gate electrodes GEL and GE2 may include forming inner electrodes PO1 between the first to fourth semiconductor patterns SP1, SP2, SP3, and SP4, and forming an outer electrode PO2 in the outer region ORG.

Gate capping patterns GP may be formed on the first and second gate electrodes GE1 and GE2. A planarization process may be performed on the gate capping patterns GP so that upper surfaces of the gate capping patterns GP are coplanar with an upper surface of the first upper insulating layer 110.

Afterwards, cutting patterns CT may be formed penetrating the first and second gate electrodes GE1 and GE2. The cutting patterns CT may extend from the gate capping patterns GP to the device isolation pattern ST. Due to the cutting patterns CT, the first and second gate electrodes GE1 and GE2 may be spaced apart from each other in the first direction D1.

Active contacts AC may be formed in the first upper insulating layer 110. Each of the active contacts AC may penetrate the first upper insulating layer 110 and be connected to at least one of the first or second source/drain patterns SD1 and SD2.

Gate contacts GC may be formed in the gate capping patterns GP. Each of the gate contacts GC may penetrate the gate capping patterns GP and be connected to the first and second gate electrodes GE1 and GE2.

Referring again to FIG. 2A, FIG. 2B, FIG. 2C, and FIG. 2D, a second upper insulating layer 120 may be formed on the first upper insulating layer 110. Upper vias UV may be formed in the second upper insulating layer 120. The upper vias UV may penetrate the second upper insulating layer 120 and be connected to the active contacts AC and the gate contacts GC.

Thereafter, the substrate 100 may be turned over so that a lower surface of the substrate 100 is exposed. A backside active contact BAC connected to at least one of the first or second source/drain patterns SD1 and SD2 may be formed on the lower surface of the substrate 100. Forming the backside active contact BAC may include removing a portion of the substrate 100 to expose the sacrificial contact pattern PH, and removing the exposed sacrificial contact pattern PH. The backside active contact BAC may be formed using a self-alignment manner using the sacrificial contact pattern PH, but is not limited thereto.

After the backside active contact BAC is formed, a power transmission network layer PDN may be formed on the lower surface of the substrate 100. Forming the power transmission network layer PDN may include forming a plurality of wire patterns and a plurality of via patterns.

According to embodiments of the inventive concept, the body portion of the separation pattern constituting the logic transistors may be formed in various shapes. Accordingly, an overlapping length of the gate electrode and the channel pattern may be variously changed for each logic transistor. That is, each logic transistor may have a different channel length. Accordingly, the logic transistors having various channel lengths may be formed in a semiconductor device.

The separation pattern of the semiconductor device according to embodiments of the inventive concept may include the body portion and the head portion having the horizontal size larger than the body portion. Additionally, the insulating layer of the head portion may include a material having an etch selectivity with respect to the body portion. The head portion may inhibit or prevent the upper portion of the body portion from being exposed, and the body portion may be protected from being unintentionally removed. Accordingly, the distance between gate electrodes spaced apart based on the separation pattern may be secured. Accordingly, the durability and electrical characteristics of the semiconductor device may be improved.

The semiconductor device according to embodiments of the inventive concept may include the inner gate spacers between the plurality of semiconductor patterns of the channel pattern and the separation pattern. The inner gate spacers including the insulating material may inhibit or prevent the leakage current occurring by the plurality of semiconductor patterns. Additionally, the horizontal length of each of the inner electrodes of the gate electrodes may be greater than the horizontal length of each of the plurality of semiconductor patterns of the channel pattern. Accordingly, the length of the plurality of semiconductor patterns vertically overlapping the inner electrodes may increase. Accordingly, the electrical characteristics of the semiconductor device may be improved.

In the semiconductor device according to embodiments of the inventive concept, the head portion and body portion of the separation pattern may be spaced apart from each other. The gate electrode may surround the plurality of semiconductor patterns of the channel pattern between the head portion and the body portion that are spaced apart from each other. Accordingly, the channel length of the channel pattern may increase. Thus, the electrical characteristics of the semiconductor device may be improved.

While embodiments are described above, a person skilled in the art may understand that many modifications and variations are made without departing from the spirit and scope of the inventive concept defined in the following claims. Accordingly, embodiments of the inventive concept should be considered in all respects as illustrative and not restrictive, with the spirit and scope of the inventive concept being indicated by the appended claims.

What is claimed is:

1. A semiconductor device comprising:
a substrate;
an active pattern on the substrate;
a first channel pattern and a second channel pattern on the active pattern;
a separation pattern between the first channel pattern and the second channel pattern;
a gate electrode on the first channel pattern and the second channel pattern; and
a gate insulating layer between the first channel pattern and the gate electrode and between the second channel pattern and the gate electrode,
wherein the separation pattern includes a body portion and a head portion on the body portion, and
wherein the head portion includes an insulating pattern and an insulating layer surrounding the insulating pattern.

2. The semiconductor device of claim 1, wherein the insulating layer of the head portion includes silicon oxycarbide (SiOC).

3. The semiconductor device of claim 1, wherein the gate insulating layer extends between the gate electrode and the separation pattern.

4. The semiconductor device of claim 1, wherein the body portion of the separation pattern extends into the active pattern.

5. The semiconductor device of claim 1, wherein the body portion and the head portion of the separation pattern are spaced apart from each other.

6. The semiconductor device of claim 1, wherein the body portion of the separation pattern includes a seam extending in a vertical direction therein, and
wherein the seam is capped by the insulating layer of the head portion of the first separation pattern.

7. The semiconductor device of claim 1, further comprising an inner gate spacer between the first channel pattern and the separation pattern and between the second channel pattern and the separation pattern.

8. The semiconductor device of claim 1, wherein a width of the head portion of the separation pattern is greater than a width of the body portion of the separation pattern.

9. The semiconductor device of claim 1, wherein an upper surface of the head portion of the separation pattern is higher than an upper surface of the gate electrode.

10. The semiconductor device of claim 1, wherein each of the first channel pattern and the second channel pattern includes a plurality of semiconductor patterns spaced apart from each other in a vertical direction, and
wherein the gate electrode surrounds each of the plurality of semiconductor patterns.

11. A semiconductor device comprising:
a substrate;
an active pattern on the substrate;
a first channel pattern and a second channel pattern disposed on the active pattern and each including a plurality of semiconductor patterns;
a separation pattern between the first channel pattern and the second channel pattern; and
a gate electrode on the first channel pattern and the second channel pattern,
wherein the separation pattern includes a body portion and a head portion on the body portion, and
wherein a portion of an uppermost semiconductor pattern among the plurality of semiconductor patterns is in contact with the head portion of the separation pattern.

12. The semiconductor device of claim 11, wherein the gate electrode includes a first portion on the first channel pattern and a second portion on the second channel pattern.

13. The semiconductor device of claim 12, wherein the first portion and the second portion of the gate electrode are spaced apart from each other by the separation pattern.

14. The semiconductor device of claim 12, wherein the body portion and the head portion of the separation pattern are spaced apart from each other, and
wherein the first portion and the second portion of the gate electrode are connected to each other between the body portion and the head portion of the separation pattern.

15. The semiconductor device of claim 11, wherein the head portion of the separation pattern includes an insulating pattern and an insulating layer surrounding the insulating pattern, and
wherein the insulating pattern and the insulating layer include different materials.

16. The semiconductor device of claim 11, further comprising:
a gate insulating layer between the first channel pattern and the gate electrode and between the second channel pattern and the gate electrode; and
an inner gate spacer between the first and second channel patterns and the separation pattern,
wherein the gate insulating layer extends between the gate electrode and the separation pattern.

17. A semiconductor device comprising:
a substrate;
a first active pattern and a second active pattern on the substrate;
a first channel pattern and a second channel pattern on each of the first active pattern and the second active pattern, respectively;
first source/drain patterns on opposing sides of the first channel pattern and second source/drain patterns on opposing sides of the second channel pattern;
a first separation pattern between the first channel pattern and the second channel pattern of the first active pattern;
a second separation pattern between the first channel pattern and the second channel patterns of the second active pattern; and
a gate electrode covering the first channel pattern and the second channel pattern on the first active pattern and the second active pattern,
wherein each of the first separation pattern and the second separation pattern includes a body portion and a head portion on the body portion, and
wherein the body portion and the head portion of at least one of the first separation pattern or the second separation pattern are spaced apart from each other.

18. The semiconductor device of claim 17, wherein the head portion includes an insulating pattern and an insulating layer surrounding the insulating pattern, and
wherein the insulating layer has an etch selectivity with respect to the insulating pattern.

19. The semiconductor device of claim 17, wherein the gate electrode is disposed between the body portion and the head portion that are spaced apart from each other.

20. The semiconductor device of claim 17, further comprising an inner gate spacer between the first source/drain patterns and the first channel pattern, and between the second source/drain patterns and the second channel pattern.
